(19) United States
(12) Patent Application Publication
(10) Pub. No.: US 2026/0047060 A1
(43) Pub. Date: Feb. 12, 2026

(54) SEMICONDUCTOR DEVICE

(71) Applicant: Samsung Electronics Co., Ltd., Suwon-si (KR)

(72) Inventors: Juho Lee, Suwon-si (KR); Sung Jin Kim, Suwon-si (KR); Sungduk Hong, Suwon-si (KR); Daewon Ha, Suwon-si (KR)

(21) Appl. No.: 19/262,430

(22) Filed: Jul. 8, 2025

(30) Foreign Application Priority Data
Aug. 9, 2024 (KR) 10-2024-0106842

(51) Int. Cl. H10B 12/00

(52) U.S. Cl. CPC H10B 12/00

(57) ABSTRACT

There is provided a semiconductor device, including a first bit line which extends in a first direction, a first channel pattern on the first surface of the first bit line, and is connected to the first bit line, a first word line which extends in a third direction, and is on the first channel pattern, a second bit line which extends in the third direction,, a first shielding conductive pattern between the first word line and the second bit line, and extends in the third direction, a second channel pattern on the second bit line, a gate insulating pattern between the first channel pattern and the first word line, and between the first channel pattern and the second channel pattern, and a second word line which extends in the first direction, and is on the second channel pattern.

### CROSS-REFERENCE TO RELATED APPLICATION

This application claims priority from Korean Patent Application No. 10-2024-0106842 filed on August. 9, 2024 in the Korean Intellectual Property Office, and all the benefits accruing therefrom under 35 U.S.C. 119, the contents of which in its entirety are herein incorporated by reference.

### BACKGROUND

The present disclosure relates to a semiconductor device, and more particularly, to a semiconductor device including a vertical channel transistor (VCT).

There is a need to increase the degree of integration of semiconductor memory devices to satisfy the performance and low price desired by consumers. In the case of the semiconductor memory device, because the degree of integration is an important factor in determining the price of a product, an increased degree of integration is particularly desired.

In the case of a two-dimensional or planar semiconductor memory device, the degree of integration is mainly determined by an area occupied by unit memory cells and is therefore greatly affected by the level of fine pattern forming technology. However, since ultra-expensive apparatuses may be needed to miniaturize the pattern, the degree of integration of the two-dimensional semiconductor memory device is increasing but is still limited. Accordingly, semiconductor memory devices including a vertical channel transistor whose channel extends in a vertical direction have been proposed.

### SUMMARY

Aspects of the present disclosure provide a semiconductor device having improved degree of integration and electrical characteristics.

However, embodiments of the present disclosure are not restricted to the one set forth herein. The above and other aspects of the present disclosure will become more apparent to one of ordinary skill in the art to which the present disclosure pertains by referencing the detailed description of the present disclosure given below.

According to some embodiments of the present disclosure, there is provided a semiconductor device including: a first bit line which extends in a first direction, and includes a first surface and a second surface or the first bit line opposite to each other in a second direction perpendicular to the first direction, in which a side wall of the first bit line extends from the first surface of the first bit line to the second surface of the first bit line, a first channel pattern on the first surface of the first bit line, and is in contact with the first bit line, a first word line which extends in a third direction perpendicular to the first direction and the second direction, and is on the first channel pattern, a second bit line which extends in the third direction, and overlaps the first word line in the second direction, a first shielding conductive pattern between the first word line and the second bit line, and extends in the third direction, a second channel pattern on the second bit line, and is in contact with the second bit line, a gate insulating pattern between the first channel pattern and the first word line, and between the first channel pattern and the second channel pattern, and a second word line which extends in the first direction, and is on the second channel pattern.

According to some embodiments of the present disclosure, there is provided a semiconductor device including, a first bit line which extends in a first direction, and includes a first surface and a second surface of the bit line that are opposite to each other in a second direction perpendicular to the first direction, in which a side wall of the first bit line extends from the first surface of the first bit line to the second surface of the first bit line, a protruding insulating pattern on the first surface of the first bit line, and includes a channel trench extending in a third direction perpendicular to the first direction and the second direction, a first channel pattern which extends along the side wall and a bottom surface of the channel trench, and is in contact with the first bit line, a first lower word line on the first channel pattern, and extends in the third direction, a second lower word line on the first channel pattern, extends in the third direction, and is spaced apart from the first lower word line in the first direction, a first upper bit line which extends in the third direction, and is in the channel trench, a second upper bit line which extends in the third direction, and is spaced apart from the first upper bit line in the first direction, a first shielding conductive pattern between the first lower word line and the first upper bit line, and between the second lower word line and the second upper bit line, a second channel pattern on the first upper bit line and the second upper bit line, and is in contact with the first upper bit line and the second upper bit line, and a second word line which extends in the first direction, and is on an upper surface of the protruding insulating pattern.

According to another aspect of the present disclosure, there is provided a semiconductor device including, a first bit line which extends in a first direction, a lower shielding conductive pattern which extends in the first direction, and is spaced apart from the first bit line in a second direction perpendicular to the first direction, a first channel pattern on the first bit line and the lower shielding conductive pattern, and is in contact with the first bit line, a first word line which extends in the second direction, and is on the first channel pattern, a second bit line which extends in the second direction, and overlaps the first word line in a third direction perpendicular to the first direction and the second direction, an intermediate shielding conductive pattern between the first word line and the second bit line, and extends in the second direction, a second channel pattern on the second bit line, and is in contact with the second bit line, a second word line which extends in the first direction, and is on the second channel pattern, and an upper shielding conductive pattern on the second word line.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail illustrative embodiments thereof with reference to the attached drawings, in which:

FIG. 1 is a circuit diagram of a semiconductor device according to some embodiments.

FIG. 2 is a perspective view of a semiconductor device according to some embodiments.

FIG. 3 is a plan view of the semiconductor device according to some embodiments.

FIGS. 4 to 6 are cross-sectional views taken along A-A, B-B, and C-C of FIG. 3.

FIG. 7 is an enlarged view of a portion P of FIG. 4.

FIGS. 8 and 9 are diagrams for explaining a semiconductor device according to some embodiments.

FIGS. 10 and 11 are diagrams for explaining the semiconductor device according to some embodiments.

FIGS. 12 to 15 are diagrams for explaining the semiconductor device according to some embodiments, respectively.

FIGS. 16 and 17 are diagrams for explaining a semiconductor device according to some embodiments.

FIGS. 18 to 45 are intermediate step diagrams for describing a semiconductor device according to some embodiments.

### DETAILED DESCRIPTION OF THE EMBODIMENTS

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Components or layers described with reference to “overlap” in a particular direction may be at least partially obstructed by one another when viewed along a line extending in the particular direction or in a plane perpendicular to the particular direction and may not necessarily be in contact with one another.

The term “connected” may be used herein to refer to a physical and/or electrical connection. When components or layers are referred to herein as “directly” on, or “in direct contact” or “directly connected,” no intervening components or layers are present. However, a first component described as being “on” a second component may not be in direct contact with said second component, and intervening components or layers may be present.

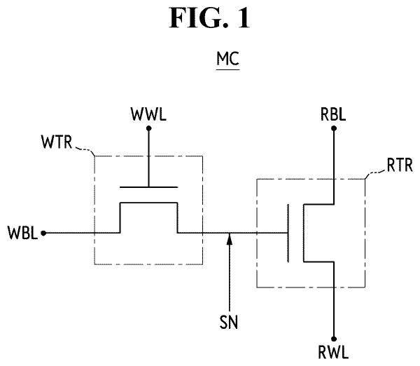

FIG. 1 is a circuit diagram of a semiconductor device according to some embodiments.

Referring to FIG. 1, a memory cell MC may include a write transistor WTR, and a read transistor RTR connected to the write transistor WTR. Although not shown, a semiconductor device according to some embodiments may include a plurality of memory cells which are arranged two-dimensionally or three-dimensionally.

The write transistor WTR may include a write word line WWL connected to a gate terminal of the write transistor WTR, and a write bit line WBL connected to a source terminal of the write transistor WTR. The read transistor RTR may include a read word line RWL and a read bit line RBL that are each connected to the source/drain terminals of the read transistor RTR.

The drain terminal of the write transistor WTR may be connected to the gate terminal of the read transistor RTR. The drain terminal of the write transistor WTR may be referred to as a storage node SN. The storage node SN may function as a gate of the read transistor RTR. The storage node SN may serve to store charge.

As an example, a program operation of the memory cell MC may be as follows. A voltage is applied to the write word line WWL and the write bit line WBL, and the write transistor WTR may be turned on. As the write transistor WTR is turned on, an electric signal (charge) may be transferred (charged) to the storage node SN. As a result, the electric signal of the write bit line WBL may be stored in the storage node SN, and as a result, a threshold voltage of the read transistor RTR may be changed.

As an example, a read operation of the memory cell MC may be as follows. The write transistor WTR is turned off, the read word line RWL holds 0V, and a voltage may be applied to the read bit line RBL. The electric signal stored in the storage node SN may be read through the current flowing through the read transistor RTR.

A semiconductor device including the memory cell MC may also be referred to as a 2T-0C (Two transistor-zero capacitor) memory element. A semiconductor device according to some embodiments may not include a separate capacitor for storing the electric charge. Therefore, an area required for forming the capacitor may be reduced, and high integration of the semiconductor device is possible.

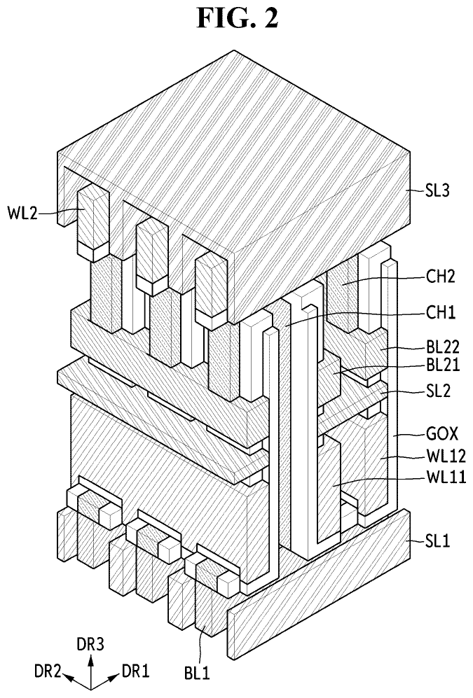

The semiconductor device including the 2T-0C memory element according to the present disclosure may include a vertical channel transistor (VCT). The vertical channel transistor may refer to a structure in which the channel of the transistor extends in a direction (a third direction DR3 of FIG. 2) perpendicular to an upper surface of the substrate 100.

Since the semiconductor device including the 2T-0C memory element includes a vertical channel transistor, the write word line WWL may be adjacent to the read word line RWL or the read bit line RBL in the vertical direction. While the memory cell MC is in operation, a voltage difference between the voltage applied to the write word line WWL during the program operation and the voltage applied to the write word line WWL during the read operation may be large. As the voltage difference applied to the write word line WWL is large, the write transistor WTR may affect the read transistor RTR. That is, an interference phenomenon may occur between the write transistor WTR and the read transistor RTR. This may cause a leakage current at the time of the operation of the adjacent memory cell MC.

In order to minimize an interference between the write transistor WTR and the read transistor RTR, a second shielding conductive pattern (SL2 of FIG. 2) including a conductive material to be described below may be disposed between the write word line WWL and the read bit line RBL, or between the write word line WWL and the read word line RWL. Accordingly, a leakage current may decrease at the time of operation of adjacent memory cells MC.

In addition, as the semiconductor device including the 2T-0C memory element includes a vertical channel transistor, the memory cells MC may be stacked in the vertical direction. Because a shielding conductive pattern is disposed between the write transistor WTR and the read transistor RTR of the memory cells MC adjacent in the vertical direction, coupling between the memory cells MC adjacent in the vertical direction may be minimized. Accordingly, the performance and reliability of the semiconductor device including the 2T-0C memory element may be improved.

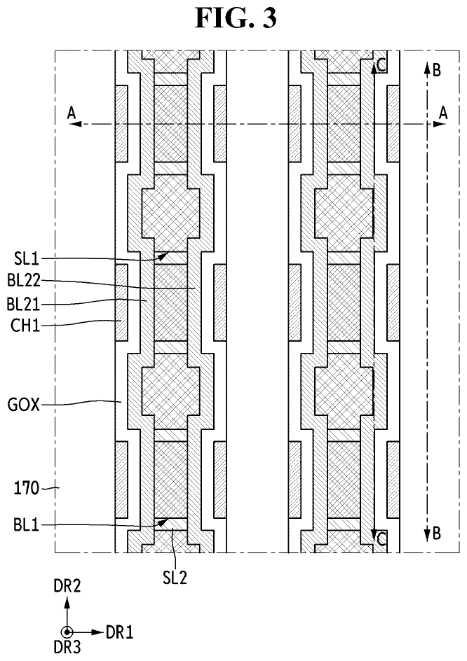

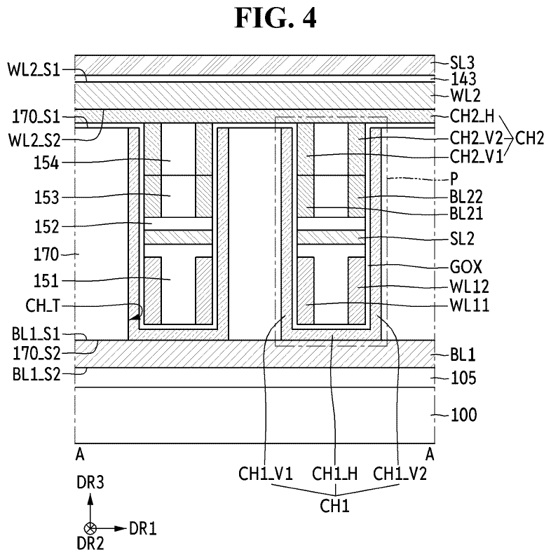

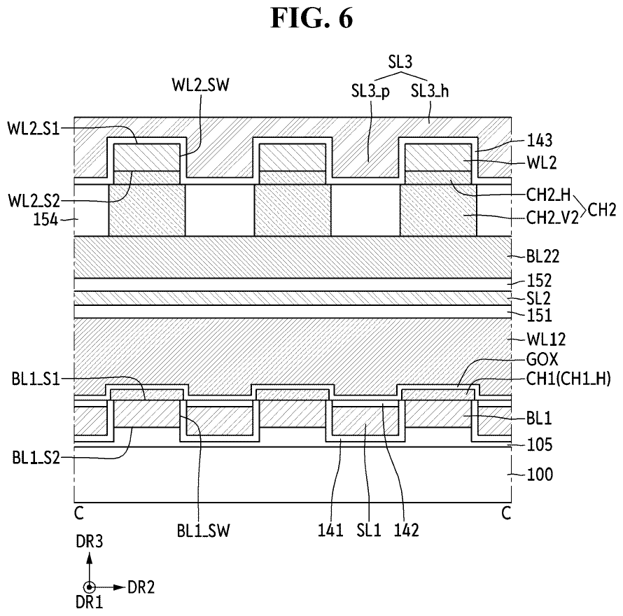

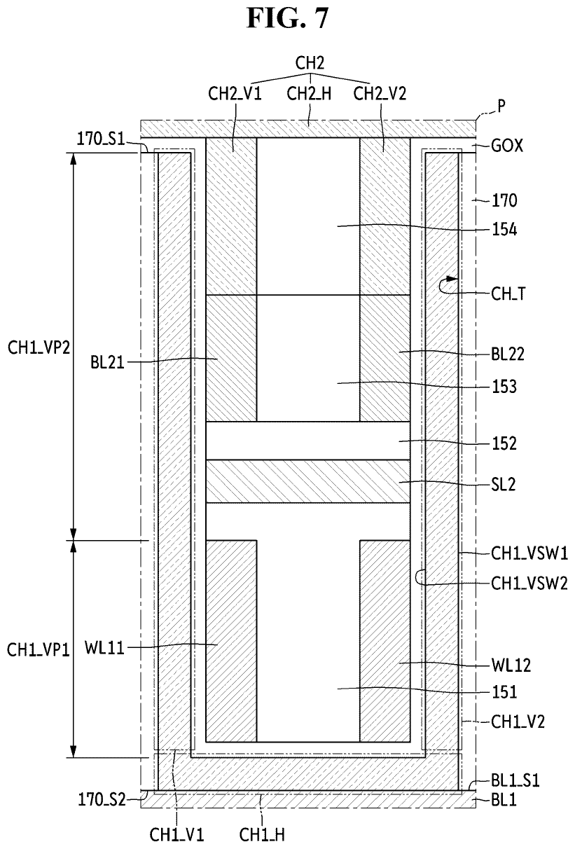

FIG. 2 is a perspective view of a semiconductor device according to some embodiments. FIG. 3 is a plan view of the semiconductor device according to some embodiments. FIGS. 4 to 6 are cross-sectional views taken along A-A, B-B, and C-C of FIG. 3. FIG. 7 is an enlarged view of a portion P of FIG. 4.

For reference, the second channel pattern CH2, the second word line WL2, and the third shielding conductive pattern SL3 are not shown in FIG. 3.

Referring to FIGS. 2 to 7, the semiconductor device according to some embodiments may include a first bit line BL1, first word lines WL11 and WL12, second bit lines BL21 and BL22, a second word line WL2, a first channel pattern CH1, a second channel pattern CH2, a first shielding conductive pattern SL1, a second shielding conductive pattern SL2, and a third shielding conductive pattern SL3.

As an example, the substrate 100 may be a silicon substrate, or may include other materials, for example, silicon germanium, indium antimonide, lead telluride, indium arsenide, indium phosphide, gallium arsenide or gallium antimonide. As another example, the substrate 100 may include a ceramic substrate, a quartz substrate or a glass substrate. As another example, the substrate 100 may include a flexible plastic substrate, such as polyimide, polyethylene terephthalate (PET), polyethylene naphthalate (PEN), poly methyl methacrylate (PMMA), polycarbonate (PC), polyethersulfone (PES) or polyester.

A lower insulating film 105 may be disposed on the substrate 100. The lower insulating film 105 may be made of an insulating material. Unlike the shown example, the lower insulating film 105 may not be disposed on the substrate 100.

The first bit lines BL1 may be disposed on the substrate 100. The first bit lines BL1 may be disposed on the lower insulating film 105.

Each of the first bit lines BL1 may extend in a first direction DR1. The first bit lines BL1 may be adjacent to each other in a second direction DR2.

The first bit line BL1 may include a first surface BL1_S1 and a second surface BL1_S2 that are opposite to each other in the third direction DR3. The second surface BL1_S2 of the first bit line may face the substrate 100.

The first bit line BL1 may include a side wall BL1_SW that connects the first surface BL1_S1 of the first bit line and the second surface BL1_S2 of the first bit line. The side wall BL1_SW of the first bit line may extend in the first direction DR1.

Here, the first direction DR1 and the second direction DR2 may be perpendicular to the third direction DR3. The first direction DR1 may intersect the second direction DR2. For example, the third direction DR3 may be a thickness direction of the substrate 100. The first direction DR1 and the second direction DR2 may be parallel to the upper surface of the substrate 100.

For example, the first bit line BL1 may correspond to the write bit line WBL of the write transistor WTR of FIG. 1.

The first bit line BL1 includes a conductive material, and may include, for example, at least one of a doped semiconductor material, a conductive metal nitride, a conductive metal silicon nitride, a metal carbonitride, a conductive metal silicide, a conductive metal oxide, a two-dimensional material, and a metal. The first bit line BL1 is shown as a single film but is not limited thereto.

In the semiconductor device according to some embodiments, the 2D material may be a metallic material and/or a semiconductor material. The 2D material may include a 2D allotrope or a 2D compound, and may include, for example, but not limited to, at least one of graphene, molybdenum disulfide (MoS₂), molybdenum diselenide (MoSe₂), tungsten diselenide (WSe₂), and/or tungsten disulfide (WS₂). That is, since the above-mentioned 2D materials are only listed as an example, the 2D materials that may be included in the semiconductor device of the present disclosure are not limited by the above-mentioned materials.

The first shielding conductive pattern SL1 may be disposed on the substrate 100. The first shielding conductive pattern SL1 may extend in the first direction DR1.

The first shielding conductive pattern SL1 may be disposed between the first bit lines BL1 adjacent to each other in the second direction DR2. The first bit line BL1 may be disposed between the first shielding conductive patterns SL1 adjacent to each other in the second direction DR2. The first shielding conductive pattern SL1 may be disposed on the side wall BL1_SW of the first bit line. The first shielding conductive pattern SL1 may extend along the side wall BL1_SW of the first bit line.

The first shielding conductive pattern SL1 includes a conductive material. The first shielding conductive pattern SL1 may include, for example, at least one of a conductive metal nitride, a conductive metal silicon nitride, a metal carbonitride, a conductive metal silicide, a conductive metal oxide, a two-dimensional material, and/or a metal.

Because the first shielding conductive pattern SL1 is disposed between the first bit lines BL1 adjacent to each other in the second direction DR2, a coupling noise between the first bit lines BL1 may be reduced.

The first shielding insulating capping film 142 may be disposed on the first shielding conductive pattern SL1. The first shielding insulating capping film 142 may be disposed on the side wall BL1_SW of the first bit line. The first shielding conductive pattern SL1 may be disposed between the first shielding insulating capping film 142 and the substrate 100. The first shielding insulating capping film 142 may be made up of an insulating material.

The first shielding insulating liner 141 may be disposed between the first shielding conductive pattern SL1 and the substrate 100. The first shielding insulating liner 141 may be disposed between the first shielding conductive pattern SL1 and the first bit line BL1 that are adjacent to each other in the second direction DR2.

The first shielding insulating liner 141 may extend along the upper surface of the substrate 100 and the side wall BL1_SW of the first bit line. The first shielding insulating liner 141 may be made of an insulating material.

A first protruding insulating pattern 170 may be disposed on the first bit line BL1 and the first shielding conductive pattern SL1. The first protruding insulating pattern 170 may be disposed on the first surface BL1_S1 of the first bit line. The first protruding insulating pattern 170 may include an insulating material.

The first protruding insulating pattern 170 may include a first surface 170_S1 and a second surface 170_S2 that are opposite to each other in the third direction DR3. The second surface 170_S2 of the first protruding insulating pattern may face the first bit line BL1 and the first shielding conductive pattern SL1. For example, the first surface 170_S1 of the first protruding insulating pattern may be an upper surface of the first protruding insulating pattern 170. The second surface 170_S2 of the first protruding insulating pattern may be a bottom surface of the first protruding insulating pattern 170.

Unlike the shown example, an etching stop film extending along the second surface 170_S2 of the first protruding insulating pattern may be further disposed between the first protruding insulating pattern 170 and the substrate 100.

The first protruding insulating pattern 170 may include a plurality of first channel trenches CH_T. Each of the first channel trenches CH_T may extend long in the second direction DR2. Adjacent first channel trenches CH_T may be spaced apart from each other in the first direction DR1.

Each of the first channel trenches CH_T may intersect the first bit line BL1. One first channel trench CH_T may expose a plurality of first bit lines BL1 adjacent to each other in the second direction DR2. The first channel trench CH_T may expose the first surface BL1_S1 of the first bit line. The first shielding conductive pattern SL1 is not exposed by the first channel trench CH_T.

The bottom surface of each first channel trench CH_T may be defined by the first bit line BL1, the first shielding insulating liner 141, and the first shielding insulating capping film 142. The side wall of each first channel trench CH_T may be defined by the first protruding insulating pattern 170.

The first channel pattern CH1 may be disposed on each first bit line BL1. For example, the first channel pattern CH1 may be disposed on the first surface BL1_S1 of each first bit line. The plurality of first channel patterns CH1 may be connected to one first bit line BL1. The plurality of first channel patterns CH1 disposed on one first bit line BL1 are spaced apart from each other in the first direction DR1.

The first channel pattern CH1 may be disposed inside a first channel trench CH_T extending in the second direction DR2. The plurality of first channel patterns CH1 may be disposed inside one first channel trench CH_T. The plurality of first channel patterns CH1 disposed inside the first channel trench CH_T are spaced apart from each other in the second direction DR2. For example, the first channel patterns CH1 may be disposed two-dimensionally along the first direction DR1 and the second direction DR2 intersecting each other.

The first channel pattern CH1 may extend along the side wall and bottom surface of the first channel trench CH_T. For example, the first channel pattern CH1 may come into contact with the first protruding insulating pattern 170. In the semiconductor device according to some embodiments, the first channel pattern CH1 may have a “U” shape in a cross section taken in the first direction DR1 and the third direction DR3.

The first channel pattern CH1 may include a horizontal portion CH1_H and a plurality of vertical portions CH1_V1 and CH1_V2. The vertical portions CH1_V1 and CH1_V2 of the first channel pattern may include a first vertical portion CH1_V1 and a second vertical portion CH1_V2 that are spaced apart from each other in the first direction DR1.

The horizontal portion CH1_H of the first channel pattern may extend along a bottom surface of the first channel trench CH_T. From the viewpoint of the cross-sectional view such as FIG. 4, the horizontal portion CH1_H of the first channel pattern may extend in the first direction DR1. The horizontal portion CH1_H of the first channel pattern may be connected to the first surface BL1_S1 of the first bit line.

The first vertical portion CH1_V1 of the first channel pattern and the second vertical portion CH1_V2 of the first channel pattern may extend along a side wall of the first channel trench CH_T. The first vertical portion CH1_V1 of the first channel pattern and the second vertical portion CH1_V2 of the first channel pattern may each protrude from the horizontal portion CH1_H of the first channel pattern in the third direction DR3. The first vertical portion CH1_V1 of the first channel pattern and the second vertical portion CH1_V2 of the first channel pattern may each extend in the third direction DR3.

The vertical portions CH1_V1 and CH1_V2 of the first channel pattern may include a first side wall CH1_VSW1 and a second side wall CH1_VSW2 that are opposite to each other in the first direction DR1. The first side wall CH1_VSW1 of the first vertical portion CH1_V1 of the first channel pattern and the first side wall CH1_VSW1 of the second vertical portion CH1_V2 of the first channel pattern may face the first protruding insulating pattern 170. The second side wall CH1_VSW2 of the first vertical portion CH1_V1 of the first channel pattern may face the second side wall CH1_VSW2 of the second vertical portion CH1_V2 of the first channel pattern.

The vertical portions CH1_V1 and CH1_V2 of the first channel pattern may include a first region CH1_VP1 and a second region CH1_VP2. The second region CH1_VP2 of the vertical portion of the first channel pattern may be disposed on the first region CH1_VP1 of the vertical portion of the first channel pattern. The first region CH1_VP1 of the vertical portion of the first channel pattern may be disposed between the horizontal portion CH1_H of the first channel pattern and the second region CH1_VP2 of the vertical portion of the first channel pattern. The first region CH1_VP1 of the vertical portion of the first channel pattern is directly connected to the horizontal portion CH1_H of the first channel pattern.

The first region CH1_VP1 of the vertical portion of the first channel pattern overlaps the first word lines WL11 and WL12 in the first direction DR1 and does not overlap the second bit lines BL21 and BL22 in the first direction DR1. The second region CH1_VP2 of the vertical portion of the first channel pattern overlaps the second bit lines BL21 and BL22 in the first direction DR1 and does not overlap the first word lines WL11 and WL12 in the first direction DR1. In FIG. 7, although the first region CH1_VP1 of the vertical portion of the first channel pattern and the second region CH1_VP2 of the vertical portion of the first channel pattern are shown as being divided in the lower part of the second shielding conductive pattern SL2, this is only for convenience of explanation, and the embodiment is not limited thereto.

For example, the first region CH1_VP1 of the vertical portion of the first channel pattern may be used as the channel region of the write transistor WTR of FIG. 1. The second region CH1_VP2 of the vertical portion of the first channel pattern may be a portion corresponding to the storage node SN of FIG. 1.

As an example, the first channel pattern CH1 may include an oxide semiconductor material. The first channel pattern CH1 may include, for example, a metal oxide. As an example, the first channel pattern CH1 may be an amorphous metal oxide film. As another example, the first channel pattern CH1 may be a polycrystalline metal oxide film. As yet another example, the first channel pattern CH1 may be in a state in which an amorphous metal oxide film and a polycrystalline metal oxide film are combined. As yet another example, the first channel pattern CH1 may be a CAAC (c-axis aligned crystalline) metal oxide film.

The first channel pattern CH1 may include, for example, but not limited to, one of indium oxide, tin oxide, zinc oxide, In—Zn-based oxide (IZO), Sn—Zn-based oxide, Al—Zn-based oxide, Zn—Mg-based oxide, Sn—Mg-based oxide, In—Mg-based oxide, In—Ga-based oxide (IGO), In—Ga—Zn-based oxide (IGZO), In—Al—Zn-based oxide, In—Sn—Zn-based oxide, Sn—Ga—Zn-based oxide, Al—Ga—Zn-based oxide, Sn—Al—Zn-based oxide, In—Hf—Zn-based oxide, In—La—Zn-based oxide, In—Ce—Zn-based oxide, In—Pr—Zn-based oxide, In—Nd—Zn-based oxide, In—Sm—Zn-based oxide, In—Eu—Zn-based oxide, In—Gd—Zn-based oxide, In—Tb—Zn-based oxide, In—Dy—Zn-based oxide, In—Ho—Zn-based oxide, In—Er—Zn-based oxide, In—Tm—Zn-based oxide, In—Yb—Zn-based oxide, In—Lu—Zn-based oxide, In—Sn—Ga—Zn-based oxide, In—Hf—Ga—Zn-based oxide, In—Al—Ga—Zn-based oxide, In—Sn—Al—Zn-based oxide, In—Sn—Hf—Zn-based oxide, and/or In—Hf—Al—Zn-based oxide.

Here, the In—Ga—Zn-based oxide means an oxide having In, Ga, and Zn as main constituents, but does not mean a ratio of In, Ga, and Zn. That is, taking IGZO (indium gallium zinc oxide) as an example, the first channel pattern CH1 may include IGZO (indium gallium zinc oxide, InₓGa_{y}Zn_{z}O). IGZO (In:Ga:Zn=1:1:1) containing indium, gallium and zinc at the same ratio may be an In—Ga—Zn-based oxide. A Ga-rich IGZO may have a higher ratio of gallium than IGZO (In:Ga:Zn=1:1:1), and a lower ratio of indium than IGZO (In:Ga:Zn=1:1:1). The Ga-rich IGZO may also be an In—Ga—Zn-based oxide. An In-rich IGZO may also have a higher ratio of indium than IGZO (In:Ga:Zn=1:1:1), and a lower ratio of gallium than IGZO (In:Ga:Zn=1:1:1). The In-rich IGZO may also be an In—Ga—Zn-based oxide.

Although the above description has been made using the IGZO, the embodiment is not limited thereto. The above description may be applied when the first channel pattern CH1 includes a ternary or more metal oxide. Also, when the first channel pattern CH1 includes the In—Ga—Zn-based oxide, the first channel pattern CH1 may further include a doped metal element other than In, Ga, and Zn.

In the semiconductor device according to some embodiments, the horizontal portion CH1_H of the first channel pattern and the first region CH1_VP1 of the vertical portion of the first channel pattern may have crystallinity, and the second region CH1_VP2 of the vertical portion of the first channel pattern may be amorphous.

In the semiconductor device according to some embodiments, the horizontal portion CH1_H of the first channel pattern and the first region CH1_VP1 of the vertical portion of the first channel pattern may have a relatively higher oxygen concentration than the second region CH1_VP2 of the vertical portion of the first channel pattern. As a result, the second region CH1_VP2 of the vertical portion of the first channel pattern may have a relatively metallicity compared to the first region CH1_VP1 of the vertical portion of the first channel pattern.

As another example, the first channel pattern CH1 may include a two-dimensional semiconductor material.

The first word lines WL11 and WL12 may be disposed on the first channel pattern CH1. The first word lines WL11 and WL12 may be disposed inside the first channel trench CH_T.

The first word lines WL11 and WL12 may be disposed on the horizontal portion CH1_H of the first channel pattern. The first word lines WL11 and WL12 may be disposed between the first vertical portion CH1_V1 of the first channel pattern and the second vertical portion CH1_V2 of the first channel pattern.

The first word lines WL11 and WL12 may include a first lower word line WL11 and a second lower word line WL12. Each of the first lower word lines WL11 and the second lower word lines WL12 may extend in the second direction DR2. The first lower word lines WL11 and the second lower word lines WL12 may be arranged alternately in the first direction DR1. The first lower word lines WL11 and the second lower word lines WL12 may be spaced apart in the first direction DR1.

The first vertical portion CH1_V1 of the first channel pattern may be disposed closer to the first lower word line WL11 than the second lower word line WL12. The first lower word line WL11 may be disposed on the second side wall CH1_VSW2 of the first vertical portion CH1_V1 of the first channel pattern. The second vertical portion CH1_V2 of the first channel pattern may be disposed closer to the second lower word line WL12 than the first lower word line WL11. The second lower word line WL12 may be disposed on the second side wall CH1_VSW2 of the second vertical portion CH1_V2 of the first channel pattern.

The first lower word line WL11 is not disposed on the first side wall CH1_VSW1 of the first vertical portion CH1_V1 of the first channel pattern. The second lower word line WL12 is not disposed on the first side wall CH1_VSW1 of the second vertical portion CH1_V2 of the first channel pattern.

For example, each of the first lower word line WL11 and the second lower word line WL12 may correspond to the write word line WWL of the write transistor WTR of FIG. 1.

The first word lines WL11 and WL12 may include a conductive material, and may include, for example, at least one of a doped semiconductor material, a conductive metal nitride, a conductive metal silicon nitride, a metal carbonitride, a conductive metal silicide, a conductive metal oxide, a two-dimensional material, and a metal. The first word lines WL11 and WL12 are shown as being single-film, but the embodiment is not limited thereto.

A first gate insulating pattern GOX may extend along a profile or perimeter of the first channel pattern CH1. For example, the first gate insulating pattern GOX may extend along the second side wall CH1_VSW2 of the first vertical portion CH1_V1 of the first channel pattern and the second side wall CH1_VSW2 of the second vertical portion CH1_V2 of the first channel pattern. The first gate insulating pattern GOX may extend along the first surface 170_S1 of the first protruding insulating pattern.

The first gate insulating pattern GOX may be disposed between the first channel pattern CH1 and the first lower word line WL11, and between the first channel pattern CH1 and the second lower word line WL12. The first gate insulating pattern GOX may be disposed between the first channel pattern CH1 and the second channel pattern CH2. The first gate insulating pattern GOX may be disposed between the first channel pattern CH1 and the second bit lines BL21 and BL22. The first gate insulating pattern GOX may be disposed between the first channel pattern CH1 and the second shielding conductive pattern SL2.

The first gate insulating pattern GOX may include a silicon oxide film, a silicon oxynitride film, a high dielectric constant insulating film having a higher dielectric constant than the silicon oxide film, or a combination thereof. The high dielectric constant insulating film may include a metal oxide or a metal oxynitride. For example, the high dielectric constant insulating film may include, but not limited to, at least one of hafnium oxide, hafnium silicon oxide, hafnium silicon oxynitride, hafnium tantalum oxide, hafnium titanium oxide, hafnium zirconium oxide, zirconium oxide, and/or aluminum oxide.

A first separation insulating pattern 151 may be disposed on the first gate insulating pattern GOX. The first separation insulating pattern 151 may be disposed in the first channel trench CH_T.

The first separation insulating pattern 151 may be disposed between the first lower word line WL11 and the second lower word line WL12 that are adjacent to each other in the first direction DR1. The first separation insulating pattern 151 may cover an upper surface of the first lower word line WL11 and an upper surface of the second lower word line WL12. The first separation insulating pattern 151 includes an insulating material.

The second shielding conductive pattern SL2 may be disposed on the first separation insulating pattern 151. The second shielding conductive pattern SL2 may be disposed inside the first channel trench CH_T. The second shielding conductive pattern SL2 may extend in the second direction DR2.

The first separation insulating pattern 151 may be disposed between the second shielding conductive pattern SL2 and the first lower word line WL11, and between the second shielding conductive pattern SL2 and the second lower word line WL12. The second shielding conductive pattern SL2 may be spatially separated from the first word lines WL11 and W12 by the first separation insulating pattern 151.

The second shielding conductive pattern SL2 may be disposed on the second side wall CH1_VSW2 of the first vertical portion CH1_V1 of the first channel pattern. The second shielding conductive pattern SL2 may be disposed on the second side wall CH1_VSW2 of the second vertical portion CH1_V2 of the first channel pattern.

The second shielding conductive pattern SL2 includes a conductive material. The second shielding conductive pattern SL2 may include, for example, at least one of a conductive metal nitride, a conductive metal silicon nitride, a metal carbonitride, a conductive metal silicide, a conductive metal oxide, a two-dimensional material, and a metal.

The second separation insulating pattern 152 may be disposed on the second shielding conductive pattern SL2. The second separation insulating pattern 152 may be disposed inside the first channel trench CH_T. The second separation insulating pattern 152 includes an insulating material.

The second bit lines BL21 and BL22 may be disposed on the second shielding conductive pattern SL2. The second bit lines BL21 and BL22 may be disposed on the second separation insulating pattern 152.

The second bit lines BL21 and BL22 may be disposed inside the first channel trench CH_T. The second bit lines BL21 and BL22 may be disposed between the first vertical portion CH1_V1 of the first channel pattern and the second vertical portion CH1_V2 of the first channel pattern.

The second bit lines BL21 and BL22 may include a first upper bit line BL21 and a second upper bit line BL22. Each of the first upper bit line BL21 and the second upper bit line BL22 may extend in the second direction DR2. The first upper bit line BL21 and the second upper bit line BL22 may be arranged alternately in the first direction DR1. The first upper bit line BL21 and the second upper bit line BL22 may be spaced apart from each other in the first direction DR1.

The first vertical portion CH1_V1 of the first channel pattern may be disposed closer to the first upper bit line BL21 than the second upper bit line BL22. The first upper bit line BL21 may be disposed on the second side wall CH1_VSW2 of the first vertical portion CH1_V1 of the first channel pattern. The second vertical portion CH1_V2 of the first channel pattern may be disposed closer to the second upper bit line BL22 than the first upper bit line BL21. The second upper bit line BL22 may be disposed on the second side wall CH1_VSW2 of the second vertical portion CH1_V2 of the first channel pattern.

The first upper bit line BL21 is not disposed on the first side wall CH1_VSW1 of the first vertical portion CH1_V1 of the first channel pattern. The second upper bit line BL22 is not disposed on the first side wall CH1_VSW1 of the second vertical portion CH1_V2 of the first channel pattern.

The first upper bit line BL21 and the first lower word line WL11 may be spaced apart from each other in the third direction DR3. The first upper bit line BL21 may overlap the first lower word line WL11 in the third direction DR3.

The second upper bit line BL22 and the second lower word line WL12 may be spaced apart from each other in the third direction DR3. The second upper bit line BL22 may overlap the second lower word line WL12 in the third direction DR3. The second shielding conductive pattern SL2 may be disposed between the first upper bit line BL21 and the first lower word line WL11, and between the second upper bit line BL22 and the second lower word line WL12.

The second separation insulating pattern 152 may be disposed between the second shielding conductive pattern SL2 and the first upper bit line BL21, and between the second shielding conductive pattern SL2 and the second upper bit line BL22. The second shielding conductive pattern SL2 may be spatially separated from the second bit lines BL21 and BL22 by the second separation insulating pattern 152.

The second bit lines BL21 and BL22 may include a conductive material, and may include, for example, at least one of a doped semiconductor material, a conductive metal nitride, a conductive metal silicon nitride, a metal carbonitride, a conductive metal silicide, a conductive metal oxide, a two-dimensional material, and/or a metal. The second bit lines BL21 and BL22 are shown as being a single film, but the embodiment is not limited thereto.

A third separation insulating pattern 153 may be disposed on the second separation insulating pattern 152. The third separation insulating pattern 153 may be disposed inside the first channel trench CH_T.

The third separation insulating pattern 153 may be disposed between the first upper bit line BL21 and the second upper bit line BL22 that are adjacent to each other in the first direction DR1. The third separation insulating pattern 153 includes an insulating material.

The second channel pattern CH2 may be disposed on the second bit lines BL21 and BL22. The second channel pattern CH2 may contact the second bit lines BL21 and BL22. The second channel pattern CH2 may be electrically connected to the second bit lines BL21 and BL22.

The second channel pattern CH2 may include a horizontal portion CH2_H and a plurality of vertical portions CH2_V1 and CH2_V2. The vertical portions CH2_V1 and CH2_V2 of the second channel pattern may protrude from the horizontal portion CH2_H of the second channel pattern toward the first bit line BL1.

The horizontal portion CH2_H of the second channel pattern may extend in the first direction DR1. The horizontal portion CH2_H of the second channel pattern may be disposed on the first surface 170_S1 of the first protruding insulating pattern. The horizontal portion CH2_H of the second channel pattern may be spaced apart from the first channel pattern CH1 in the third direction DR3.

The vertical portions CH2_V1 and CH2_V2 of the second channel pattern may extend in the third direction DR3. The vertical portions CH2_V1 and CH2_V2 of the second channel pattern may be directly connected to the horizontal portion CH2_H of the second channel pattern. The vertical portions CH2_V1 and CH2_V2 of the second channel pattern may be disposed inside the first channel trench CH_T.

The vertical portions CH2_V1 and CH2_V2 of the second channel pattern may include a first vertical portion CH2_V1 and a second vertical portion CH2_V2. The first vertical portion CH2_V1 of the second channel pattern and the second vertical portion CH2_V2 of the second channel pattern may be arranged alternately in the first direction DR1. The first vertical portion CH2_V1 of the second channel pattern and the second vertical portion CH2_V2 of the second channel pattern may be spaced apart from each other in the first direction DR1.

The first vertical portion CH2_V1 of the second channel pattern may contact the first upper bit line BL21. The second vertical portion CH2_V2 of the second channel pattern may contact the second upper bit line BL22.

The first vertical portion CH2_V1 of the second channel pattern and the second vertical portion CH2_V2 of the second channel pattern may each overlap the first channel pattern CH1 in the first direction DR1. For example, the first vertical portion CH2_V1 of the second channel pattern and the second vertical portion CH2_V2 of the second channel pattern may each overlap the vertical portions CH1_V1 and CH1_V2 of the first channel pattern in the first direction DR1.

The first vertical portion CH2_V1 of the second channel pattern may be disposed on the second side wall CH1_VSW2 of the first vertical portion CH1_V1 of the first channel pattern. The second vertical portion CH2_V2 of the second channel pattern may be disposed on the second side wall CH1_VSW2 of the second vertical portion CH1_V2 of the first channel pattern.

As an example, the second channel pattern CH2 may include an oxide semiconductor material or a two-dimensional semiconductor material, like the first channel pattern CH1.

As another example, the second channel pattern CH2 may include a material different from the first channel pattern CH1. For example, the first channel pattern CH1 may include an oxide semiconductor material, and the second channel pattern CH2 may include polycrystalline silicon. The polycrystalline silicon may include a doped impurity element.

A fourth separation insulating pattern 154 may be disposed on the third separation insulating pattern 153. The fourth separation insulating pattern 154 may be disposed inside the first channel trench CH_T. The horizontal portion CH2_H of the second channel pattern may be disposed on the fourth separation insulating pattern 154.

The fourth separation insulating pattern 154 may be disposed between the first vertical portion CH2_V1 of the second channel pattern and the second vertical portion CH1_V2 of the first channel pattern that are adjacent to each other in the first direction DR1. The fourth separation insulating pattern 154 includes an insulating material.

The second word line WL2 may be disposed on the second channel pattern CH2. The second word line WL2 may be disposed on the first surface 170_S1 of the first protruding insulating pattern.

Each second word line WL2 may extend in the first direction DR1. The second word lines WL2 may be adjacent to each other in the second direction DR2.

The second word line WL2 may include a first surface WL2_S1 and a second surface WL2_S2 that are opposite to each other in the third direction DR3. The second surface WL2_S2 of the second word line may face the second channel pattern CH2.

The second word line WL2 may include a side wall WL2_SW that connects the first surface WL2_S1 of the second word line and the second surface WL2_S2 of the second word line. The side wall WL2_SW of the second word line may extend in the first direction DR1.

The second word line WL2 may be connected to the second channel pattern CH2. For example, the second word line WL2 may be connected to the horizontal portion CH2_H of the second channel pattern. The second surface WL2_S2 of the second word line may be connected to the horizontal portion CH2_H of the second channel pattern. The second word line WL2 may contact the horizontal portion CH2_H of the second channel pattern.

As an example, each of the first upper bit line BL21 and the second upper bit line BL22 may correspond to the read bit line RBL of the read transistor RTR of FIG. 1. The second word line WL2 may correspond to the read word line RWL of the read transistor RTR of FIG. 1.

As another example, each of the first upper bit line BL21 and the second upper bit line BL22 may correspond to the read word line RWL of the read transistor RTR of FIG. 1. The second word line WL2 may correspond to the read bit line RBL of the read transistor RTR of FIG. 1.

The second word line WL2 may include a conductive material, and may include, for example, at least one of a doped semiconductor material, a conductive metal nitride, a conductive metal silicon nitride, a metal carbonitride, a conductive metal silicide, a conductive metal oxide, a two-dimensional material, and a metal. The second word line WL2 is shown as being a single film, but the embodiment is not limited thereto.

The third shielding conductive pattern SL3 may be disposed on the second word line WL2. The third shielding conductive pattern SL3 may be disposed on the second channel pattern CH2.

The third shielding conductive pattern SL3 may be disposed on the side wall WL2_SW of the second word line. In the semiconductor device according to some embodiments, the third shielding conductive pattern SL3 may be disposed on the first surface WL2_S1 of the second word line.

The third shielding conductive pattern SL3 may include a first shielding conductive plate SL3_h and a plurality of first shielding conductive line patterns SL3_p. The first shielding conductive plate SL3_h may have a flat plate shape. The first shielding conductive plate SL3_h may be disposed on the first surface WL2_S1 of the second word line.

Each first shielding conductive line pattern SL3_p may extend in the first direction DR1. Each first shielding conductive line pattern SL3_p may be adjacent to each other in the second direction DR2. The first shielding conductive line pattern SL3_p may be disposed between the second word lines WL2 adjacent to each other in the second direction DR2. The first shielding conductive line pattern SL3_p may be disposed on the side wall WL2_SW of the second word line.

The first shielding conductive line pattern SL3_p may protrude from the first shielding conductive plate SL3_h in the third direction DR3. The first shielding conductive line pattern SL3_p may be directly connected to the first shielding conductive plate SL3_h.

The third shielding conductive pattern SL3 includes a conductive material. The third shielding conductive pattern SL3 may include, for example, at least one of a conductive metal nitride, a conductive metal silicon nitride, a metal carbonitride, a conductive metal silicide, a conductive metal oxide, a two-dimensional material, and a metal.

The third shielding conductive pattern SL3 may be disposed between the second word lines WL2 adjacent to each other in the second direction DR2, thereby reducing a coupling noise between the second word lines WL2.

A second shielding insulating liner 143 may be disposed between the third shielding conductive pattern SL3 and the second word line WL2. The second shielding insulating liner 143 may extend along a boundary between the third shielding conductive pattern SL3 and the second word line WL2. The second shielding insulating liner 143 may be made of an insulating material.

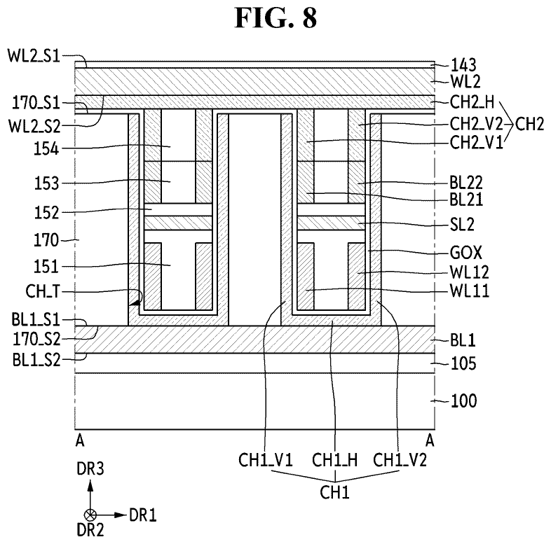

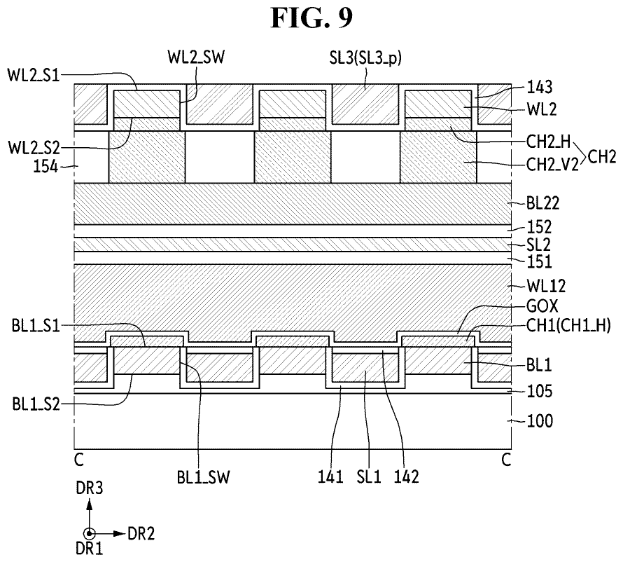

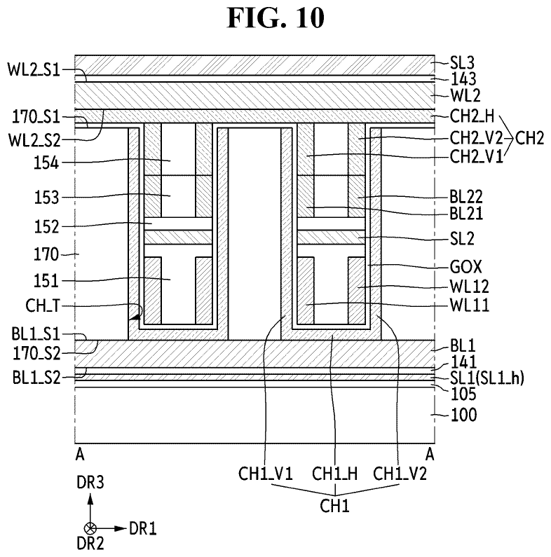

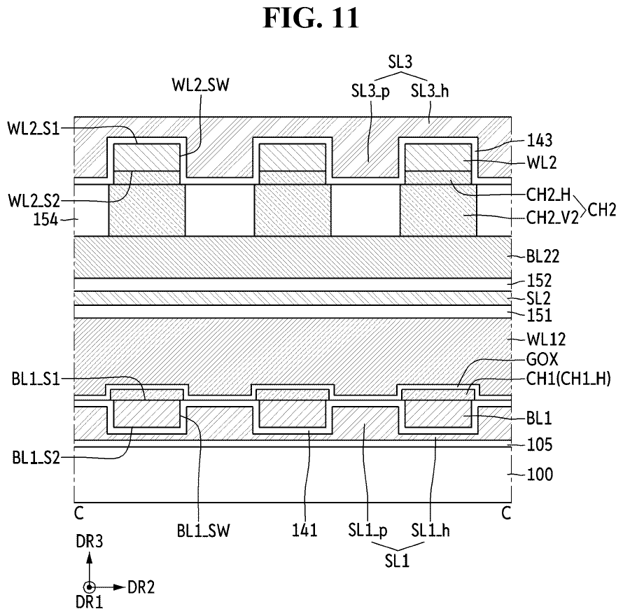

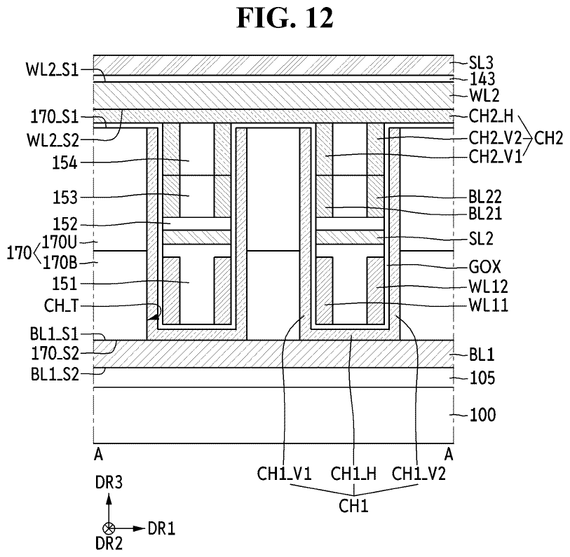

FIGS. 8 and 9 are diagrams for explaining a semiconductor device according to some embodiments. FIGS. 10 and 11 are diagrams for explaining the semiconductor device according to some embodiments. FIGS. 12 to 15 are diagrams for explaining the semiconductor device according to some embodiments, respectively. For convenience of explanation, differences from those described using FIGS. 2 to 7 will be mainly described.

Referring to FIGS. 8 and 9, in the semiconductor device according to some embodiments, the third shielding conductive pattern SL3 is not disposed on the first surface WL2_S1 of the second word line.

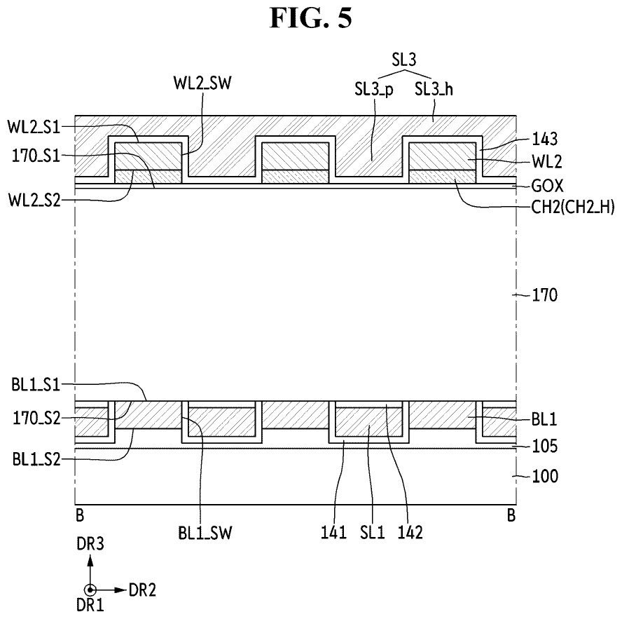

The third shielding conductive pattern SL3 may not include the first shielding conductive plate (SL3_h of FIG. 5). The third shielding conductive pattern SL3 may include only a plurality of first shielding conductive line patterns SL3_p.

Referring to FIGS. 10 and 11, in the semiconductor device according to some embodiments, the first shielding conductive pattern SL1 may be disposed on the second face BL1_S2 of the first bit line.

The first shielding conductive pattern SL1 may include a second shielding conductive plate SL1_h and a plurality of second shielding conductive line patterns SL1_p. The second shielding conductive plate SL1_h may have a flat plate shape. The second shielding conductive plate SL1_h may be disposed on the second face BL1_S2 of the first bit line. The second shielding conductive plate SL1_h may be disposed between the first bit line BL1 and the substrate 100.

The second shielding conductive line pattern SL1_p may be disposed between the first bit lines BL1 adjacent to each other in the second direction DR2. The second shielding conductive line pattern SL1_p may be disposed on the side wall BL1_SW of the first bit line.

The second shielding conductive line pattern SL1_p may protrude from the second shielding conductive plate SL1_h in the third direction DR3. The second shielding conductive line pattern SL1_p may be directly connected to the second shielding conductive plate SL1_h.

The first shielding insulating liner 141 may extend along the profile or perimeter of the first shielding conductive pattern SL1. The first shielding insulating liner 141 may cover, overlap, or be on the uppermost face of the second shielding conductive line pattern SL1_p. Therefore, the first shielding insulating capping film (142 of FIG. 4) may not be disposed between the first shielding conductive pattern SL1 and the first channel pattern CH1.

Referring to FIG. 12, in the semiconductor device according to some embodiments, the first protruding insulating pattern 170 may include a first lower protruding insulating pattern 170B and a first upper protruding insulating pattern 170U.

The first lower protruding insulating pattern 170B and the first upper protruding insulating pattern 170U may include different materials from each other. For example, the first lower protruding insulating pattern 170B may include silicon oxide, and the first upper protruding insulating pattern 170U may include silicon nitride.

In FIG. 7, the first region CH1_VP1 of the vertical portion of the first channel pattern and the second region CH1_VP2 of the vertical portion of the first channel pattern may be divided at a boundary between the first lower protruding insulating pattern 170B and the first upper protruding insulating pattern 170U.

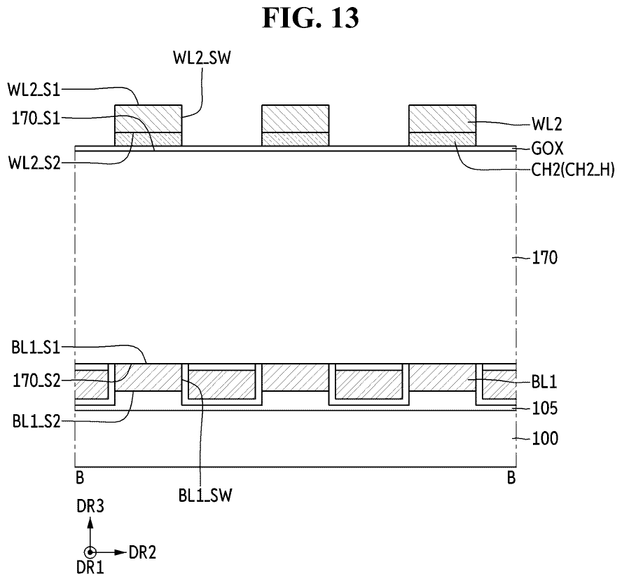

In the embodiment of FIG. 13, a difference in oxygen concentration between the first region CH1_VP1 of the vertical portion of the first channel pattern and the second region CH1_VP2 of the vertical portion of the first channel pattern may be caused through a thermal process. For example, after the first protruding insulating pattern 170 and the first channel pattern CH1 are formed, the thermal process may be performed. The difference in oxygen concentration may be caused through such a thermal process. Since the first lower protruding insulating pattern 170B includes an oxide, oxygen of the first lower protruding insulating pattern 170B may be diffused into the first region CH1_VP1 of the vertical portion of the first channel pattern, while the thermal process is being performed. Since the first upper protruding insulating pattern 170U does not include an oxide, oxygen may not be diffused into the second region CH1_VP2 of the vertical portion of the first channel pattern, while the thermal process is being performed. Accordingly, the oxygen concentration in the second region CH1_VP2 of the vertical portion of the first channel pattern may be relatively lower than that in the first region CH1_VP1 of the vertical portion of the first channel pattern. As a result, the second region CH1_VP2 of the vertical portion of the first channel pattern may have a relatively metallicity compared to the first region CH1_VP1 of the vertical portion of the first channel pattern.

Referring to FIG. 13, the semiconductor device according to some embodiments may not include the third shielding conductive pattern (SL3 of FIG. 5).

The third shielding conductive pattern SL3 may not be disposed between the second word lines WL2 adjacent to each other in the second direction DR2.

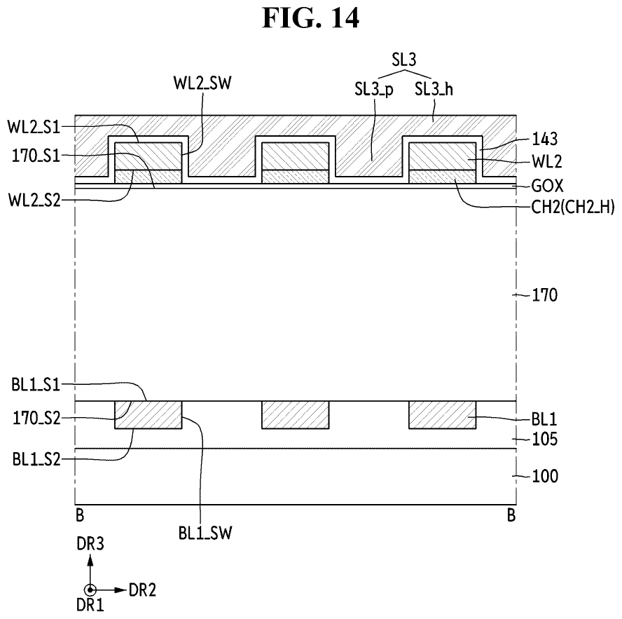

Referring to FIG. 14, the semiconductor device according to some embodiments may not include the first shielding conductive pattern (SL1 of FIG. 5).

The first shielding conductive pattern SL1 may not be disposed between the first bit lines BL1 adjacent to each other in the second direction DR2. The first bit line BL1 may be disposed inside the lower insulating film 105.

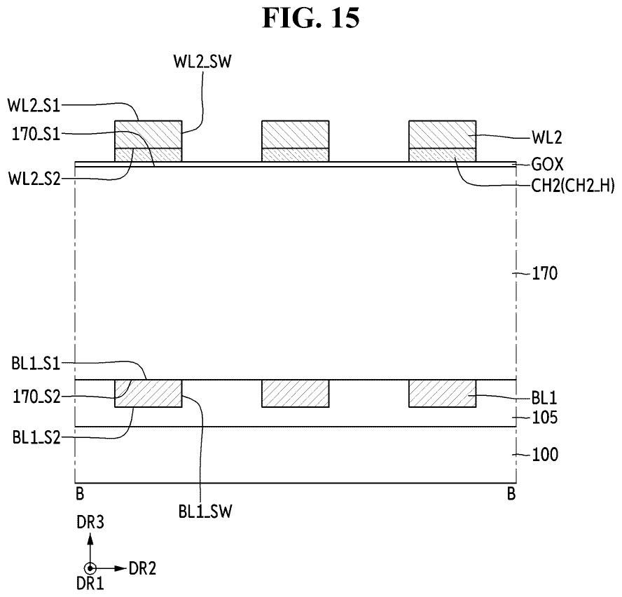

Referring to FIG. 15, the semiconductor device according to some embodiments may not include the first shielding conductive pattern (SL1 of FIG. 5) and the third shielding conductive pattern (SL3 of FIG. 5).

A shielding conductive pattern including a conductive material may not be disposed between the first bit lines BL1 adjacent in the second direction DR2 and the second word lines WL2 adjacent in the second direction DR2.

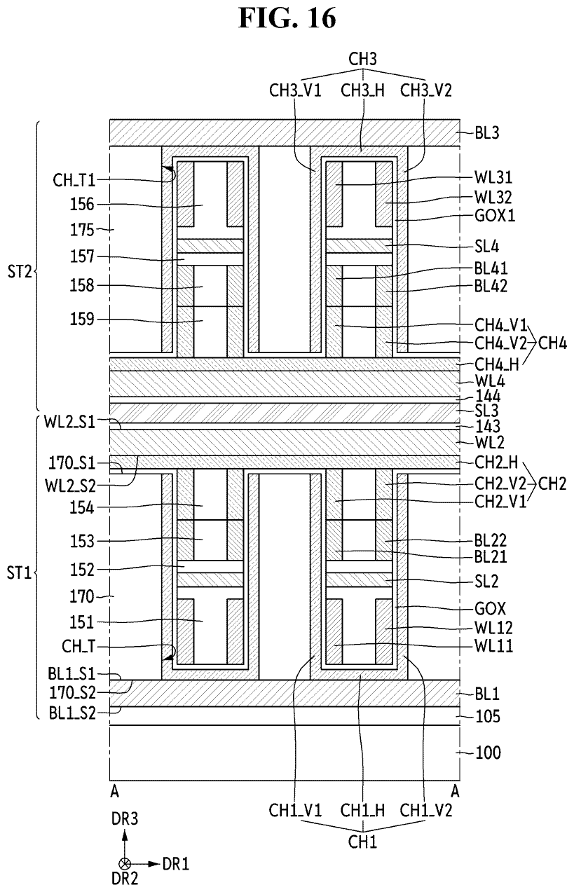

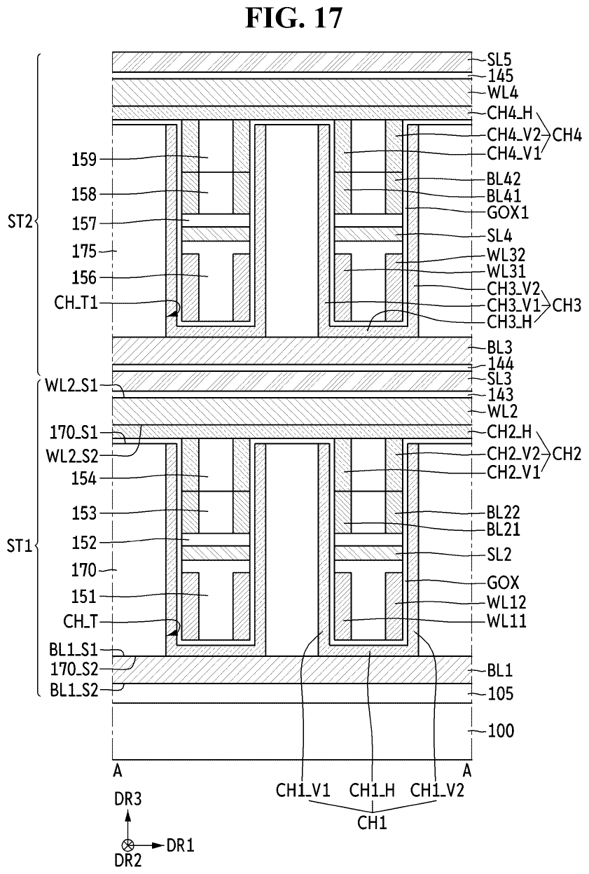

FIGS. 16 and 17 are diagrams for explaining a semiconductor device according to some embodiments. For convenience of explanation, the following description will focus on differences from those described using FIGS. 2 to 7.

Referring to FIGS. 16 and 17, the semiconductor device according to some embodiments may include a first memory structure ST1 and a second memory structure ST2 that are stacked in the third direction DR3.

The second memory structure ST2 may be disposed on the first memory structure ST1.

For example, the semiconductor device described above referring to FIGS. 2 to 7 may constitute the first memory structure ST1. That is to say, the first memory structure ST1 may include a first bit line BL1, first word lines WL11 and WL12, second bit lines BL21 and BL22, a second word line WL2, a first channel pattern CH1, a second channel pattern CH2, a first shielding conductive pattern SL1, a second shielding conductive pattern SL2, and a third shielding conductive pattern SL3.

The following description will focus on the second memory structure ST2.

The second memory structure ST2 may include a third bit line BL3, third word lines WL31 and WL32, fourth bit lines BL41 and BL42, a fourth word line WL4, a third channel pattern CH3, a fourth channel pattern CH4, a third shielding conductive pattern SL3, a fourth shielding conductive pattern SL4, and a fifth shielding conductive pattern SL5. For example, the third shielding conductive pattern SL3 may be shared by the first memory structure ST1 and the second memory structure ST2.

The description of the third bit line BL3, the third word lines WL31 and WL32, the fourth bit lines BL41 and BL42, the fourth word line WL4, the third channel pattern CH3, and the fourth channel pattern CH4 that are included in the second memory structure ST2 may be substantially the same as the description of the first bit line BL1, the first word lines WL11 and WL12, the second bit lines BL21 and BL22, the second word line WL2, the first channel pattern CH1, and the second channel pattern CH2 that are included in the first memory structure ST1.

The third channel pattern CH3 may include a horizontal portion CH3_H, a first vertical portion CH3_V1, and a second vertical portion CH3_V2. The fourth channel pattern CH4 may include a horizontal portion CH4_H, a first vertical portion CH4_V1, and a second vertical portion CH4_V2.

The second gate insulating pattern GOX1 may be disposed between the third channel pattern CH3 and the third word lines WL31 and WL32. The second gate insulating pattern GOX1 may be disposed between the third channel pattern CH3 and the fourth channel pattern CH4. The second gate insulating pattern GOX1 may be disposed between the third channel pattern CH3 and the fourth bit lines BL41 and BL42. The second gate insulating pattern GOX1 may be disposed between the third channel pattern CH3 and the fourth shielding conductive pattern SL4.

The second protruding insulating pattern 175 may include a second channel trench CH_T1 extending in the second direction DR2. The third word lines WL31 and WL32, the fourth bit lines BL41 and BL42, the third channel pattern CH3, and the vertical portions CH4_V1 and CH4_V2 of the fourth channel pattern may be disposed inside the second channel trench CH_T1.

The fourth shielding conductive pattern SL4 may be disposed inside the second channel trench CH_T1. The fourth shielding conductive pattern SL4 may extend in the second direction DR2. The fourth shielding conductive pattern SL4 may be disposed between the third word lines WL31 and WL32 and the fourth bit lines BL41 and BL42.

A fifth separation insulating pattern 156, a sixth separation insulating pattern 157, a seventh separation insulating pattern 158, and an eighth separation insulating pattern 159 may each be disposed in the second channel trench CH_T1.

In FIG. 16, the fifth shielding conductive pattern SL5 is not shown, but the fifth shielding conductive pattern SL5 may be disposed to be adjacent to the third bit line BL3 in the second direction DR2, similarly to that shown in FIG. 5.

In FIG. 16, a second memory structure ST2 including the third bit line BL3, the third word lines WL31 and WL32, the fourth bit lines BL41 and BL42, and the fourth word line WL4 may be sequentially formed on a supporting substrate. The supporting substrate including the second memory structure ST2 may be bonded to the substrate 100. The supporting substrate may then be removed. Bonding between the supporting substrate and the substrate 100 may be performed, using the third shielding conductive pattern SL3.

Accordingly, the fourth word line WL4 may be disposed between the third shielding conductive pattern SL3 and the fourth channel pattern CH4. The third shielding insulating liner 144 may be disposed between the fourth word line WL4 and the third shielding conductive pattern SL3.

In FIG. 17, a second memory structure ST2 may be formed on the substrate 100 on which the first memory structure ST1 is formed. The third bit line BL3 may be disposed between the third shielding conductive pattern SL3 and the third channel pattern CH3. The third shielding insulating liner 144 may be disposed between the third bit line BL3 and the third shielding conductive pattern SL3. The fourth shielding insulating liner 145 may be disposed between the fourth word line WL4 and the fifth shielding conductive pattern SL5. In a cross-sectional view taken in the second direction DR2, a boundary shape between the third shielding conductive pattern SL3 and the third bit line BL3 may be similar to that of FIG. 11.

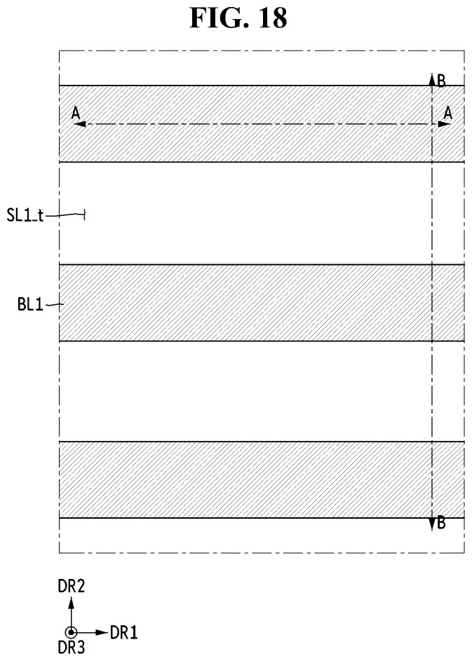

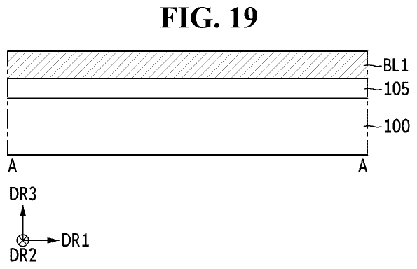

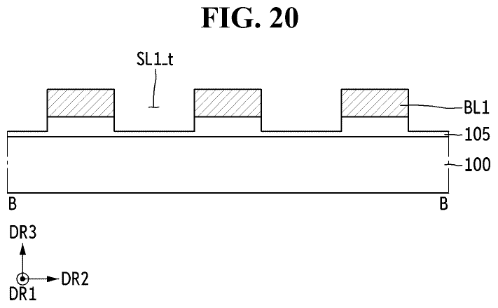

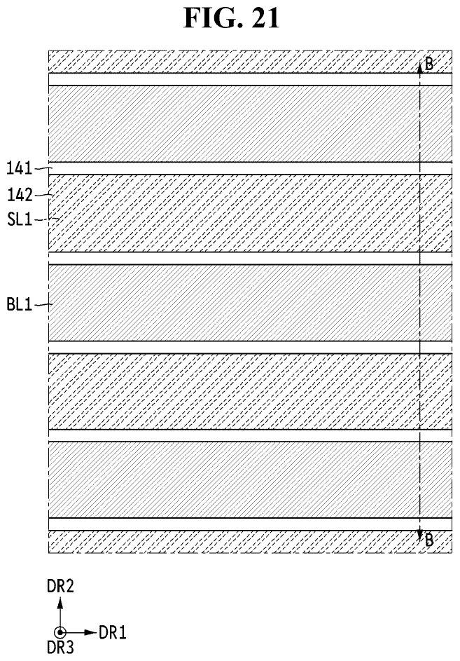

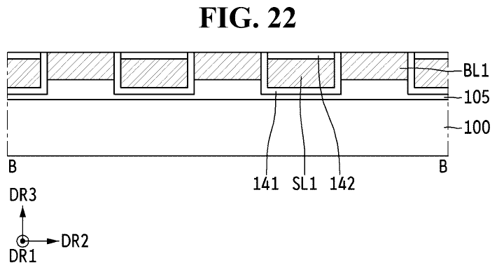

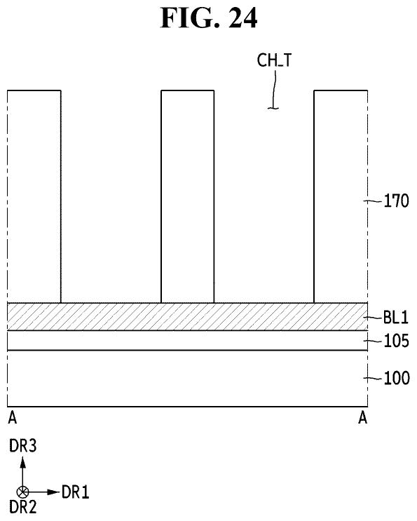

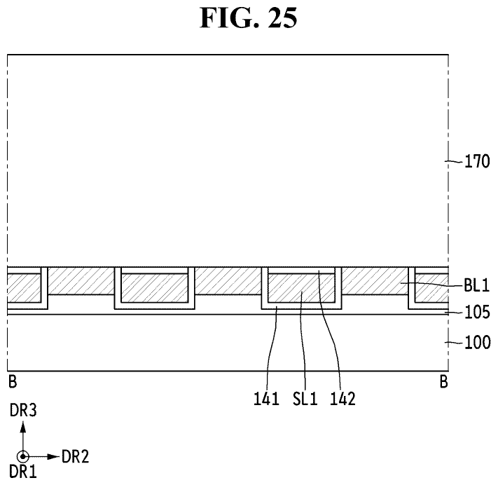

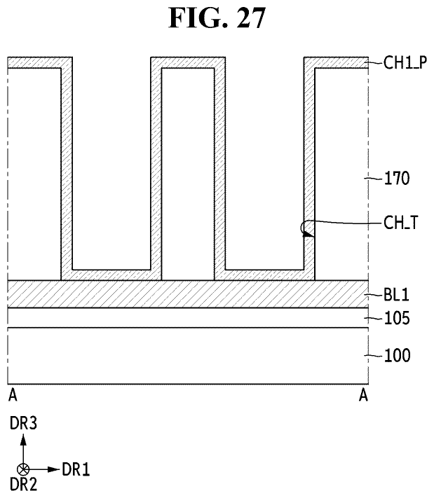

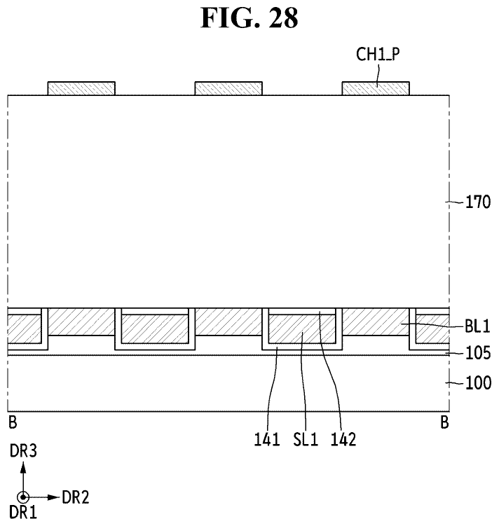

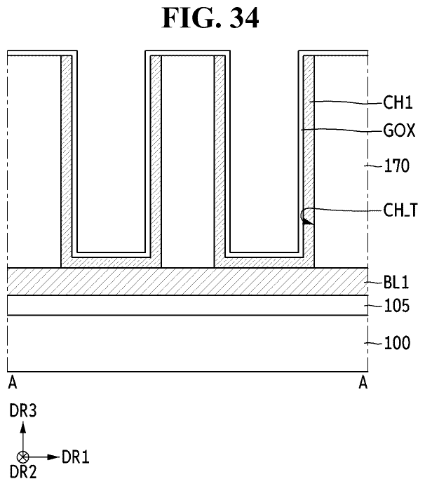

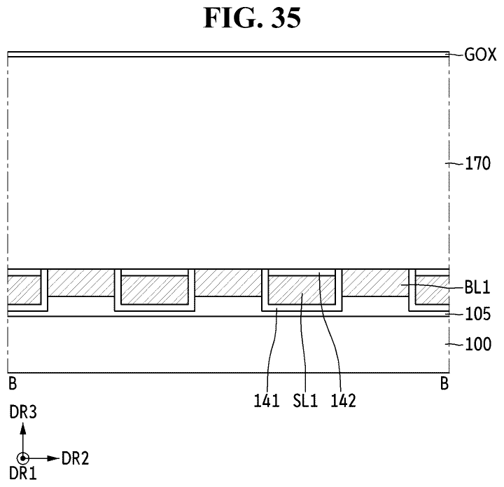

FIGS. 18 to 45 are intermediate step diagrams for describing a semiconductor device according to some embodiments. For simplification of the description, descriptions of repeated contents of those described above will be simplified or omitted.

Referring to FIGS. 18 to 20, the first bit line BL1 may be formed on the substrate 100.

More specifically, the lower insulating film 105 may be formed on the substrate 100. The first bit line film may be formed on the lower insulating film 105. The first bit line film may be patterned to form the first bit line BL1.

While the first bit line BL1 is being formed, a first shielding pattern trench SL1_t may be formed between the first bit lines BL1 adjacent to each other in the second direction DR2.

Referring to FIGS. 18 to 22, the first shielding conductive pattern SL1 may be formed inside the first shielding pattern trench SL1_t.

The first shielding conductive pattern SL1 may be formed in the first bit lines BL1 adjacent to each other in the second direction DR2.

The first shielding insulating liner 141 may be formed between the first shielding conductive pattern SL1 and the first bit line BL1. The shielding insulating capping film 142 may be formed on the first shielding conductive pattern SL1. The shielding insulating capping film 142 may be formed inside the first shielding pattern trench SL1_t.

More specifically, the shielding insulating liner film may be formed along the side wall and bottom surface of the first shielding pattern trench SL1_t. The shielding insulating liner film may be formed along the upper surface of the first bit line BL1. The first shielding conductive pattern SL1 may be formed on the shielding insulating liner film. The first shielding conductive pattern SL1 may fill a part of the first shielding pattern trench SL1_t. The upper surface of the first shielding conductive pattern SL1 may be lower than the upper surface of the first bit line BL1. Next, the shielding insulating capping film 142 may be formed on the first shielding conductive pattern SL1. A part of the shielding insulating capping film 142 and a part of the shielding insulating liner film may be removed to expose the first bit line BL1. Thus, the first shielding insulating liner 141 may be formed.

Unlike those shown in FIGS. 18 to 22, the first shielding conductive pattern SL1 may be formed on the substrate 100. Next, the first bit line BL1 may be formed on the first shielding conductive pattern SL1. In such a case, the first shielding conductive pattern SL1 may have a shape as shown in FIGS. 10 and 11.

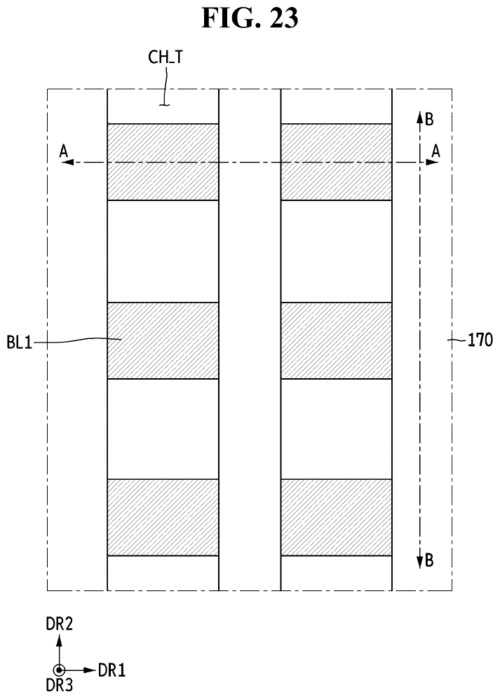

Referring to FIGS. 23 to 25, the first protruding insulating pattern 170 may be formed on the first bit line BL1 and the first shielding conductive pattern SL1.

The first protruding insulating pattern 170 may include a plurality of first channel trenches CH_T that expose the first bit line BL1.

More specifically, a protruding insulating film may be formed on the first bit line BL1 and the first shielding conductive pattern SL1. The first channel trench CH_T may be formed in the protruding insulating film. Thus, the first protruding insulating pattern 170 may be formed.

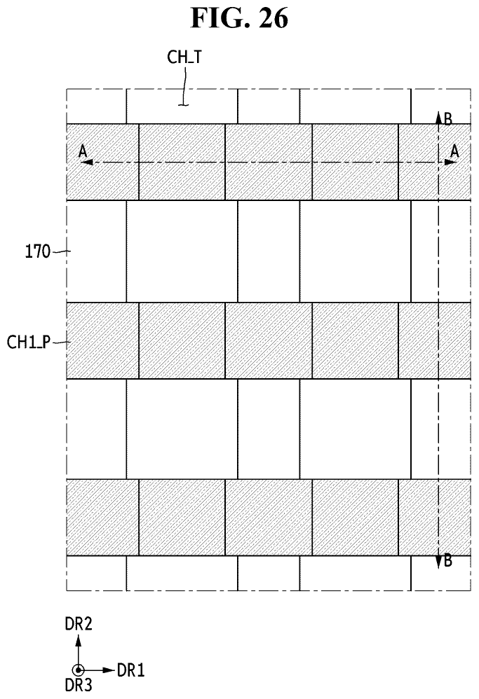

Referring to FIGS. 26 to 28, a plurality of pre-channel patterns CH1_P may be formed along the side wall and bottom surface of the first channel trench CH_T.

The plurality of pre-channel patterns CH1_P may be formed along the upper surface of the first protruding insulating pattern 170. Each pre-channel pattern CH1_P may be spaced apart from each other in the second direction DR2.

More specifically, a pre-channel film may be formed on the first protruding insulating pattern 170. The pre-channel film may be formed entirely on the side walls and bottom surface of the first channel trench CH_T. The pre-channel film may entirely cover, overlap, or be on the upper surface of the first protruding insulating pattern 170. The pre-channel film may then be patterned, using a photo process. Accordingly, the pre-channel pattern CH1_P extending in the first direction DR1 may be formed.

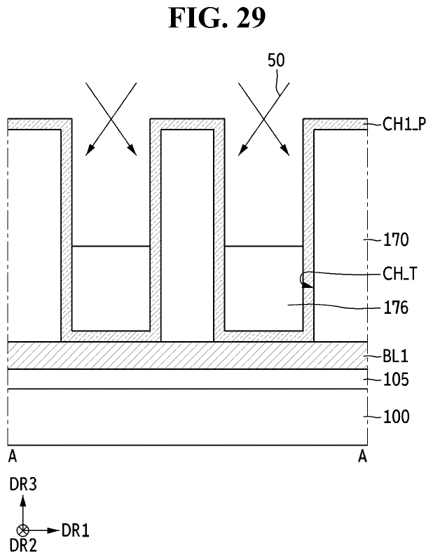

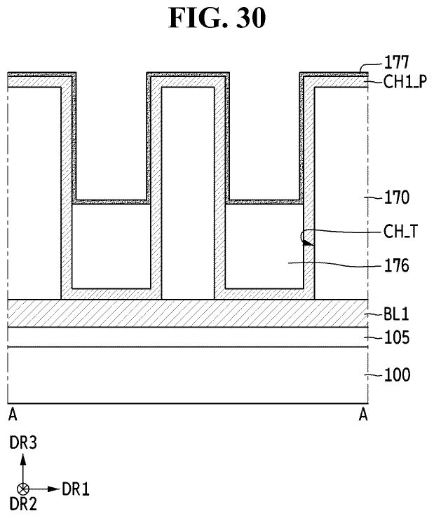

Referring to FIGS. 29 and 30, a sacrificial pattern 176 may be formed on the pre-channel pattern CH1_P.

The sacrificial pattern 176 may fill a part of the first channel trench CH_T.

In FIG. 29, after forming the sacrificial pattern 176, an implant process 50 may be performed. The implant process 50 may implant a material, such as boron (B), argon (Ar), and/or fluorine (F), into the pre-channel pattern CH1_P. The implant process 50 may proceed in a tilted state. Since the sacrificial pattern 176 serves as a mask, the portion of the pre-channel pattern CH1_P that is blocked with the sacrificial pattern 176 may not be affected by the implant process 50. That is, physical damage may be caused to a part of the pre-channel pattern CH1_P through the implant process 50. While the implant process 50 is proceeding, the pre-channel pattern CH1_P that is blocked with the sacrificial pattern 176 may not be physically damaged by the implant process 50. Oxygen may escape from the pre-channel pattern CH1_P that is physically damaged through the implant process 50. As a result, a portion with a relatively low oxygen concentration may be formed inside the pre-channel pattern CH1_P.

Accordingly, the portion with a relatively low oxygen concentration inside the pre-channel pattern CH1_P may have metallicity compared to other portions.

In FIG. 30, an impurity film 177 may be formed on the pre-channel pattern CH1_P and the sacrificial pattern 176. The impurity film 177 may be in direct contact with the pre-channel pattern CH1_P that is not covered by or not overlapped by the sacrificial pattern 176. The impurity film 177 may include, for example, boron (B). After forming the impurity film 177, the boron B contained in the impurity film 177 may be diffused into the pre-channel pattern CH1_P that is not covered with or not overlapped with the sacrificial pattern 176 through a thermal process. As a result, the portion of the pre-channel pattern CH1_P into which the boron B is diffused may have a relatively higher metallicity than the portion into which the boron is not diffused.

Next, the sacrificial pattern 176 on the pre-channel pattern CH1_P may be removed.

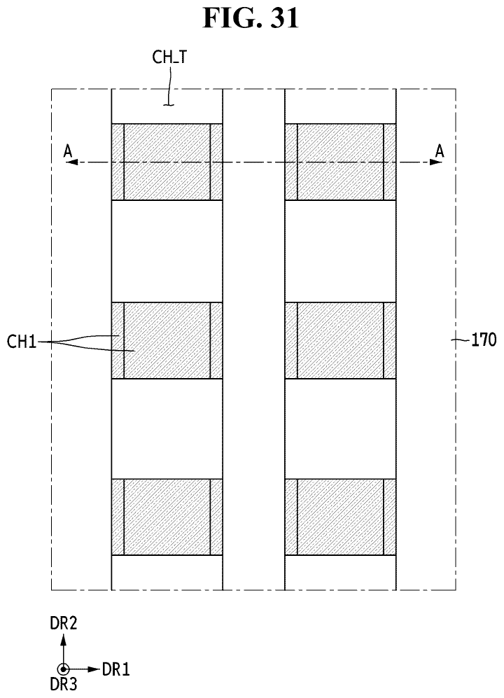

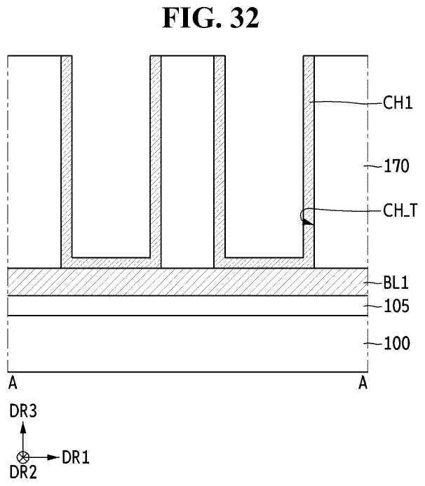

Manufacturing processes described using FIGS. 29 and 30 are selectively applicable processes. Therefore, the manufacturing processes described using FIGS. 31 and 32 may be performed without the manufacturing processes described using FIGS. 29 and 30.

Referring to FIGS. 31 and 32, the pre-channel pattern CH1_P formed on the upper surface of the first protruding insulating pattern 170 may be removed to form the first channel pattern CH1.

The first channel pattern CH1 may be formed along the side wall and bottom surface of the first channel trench CH_T. The first channel pattern CH1 may contact the first bit line BL1 exposed by the first channel trench CH_T.

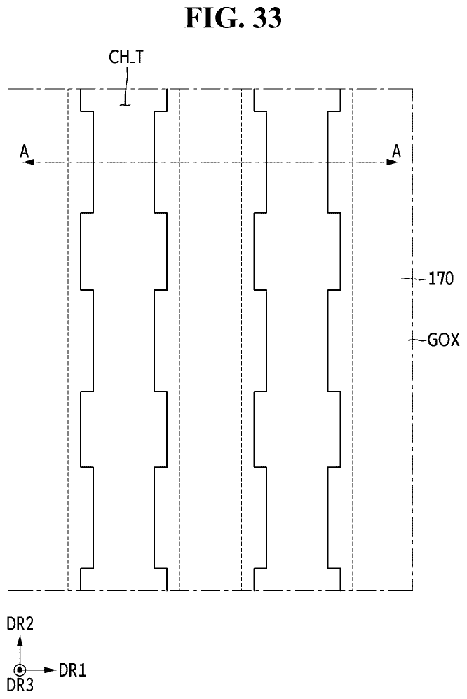

Referring to FIGS. 33 to 35, the first gate insulating pattern GOX may be formed on the entire face of the substrate 100.

The first gate insulating pattern GOX may be formed along the profile of the first channel pattern CH1. The first gate insulating pattern GOX may be formed on the upper surface of the first protruding insulating pattern 170.

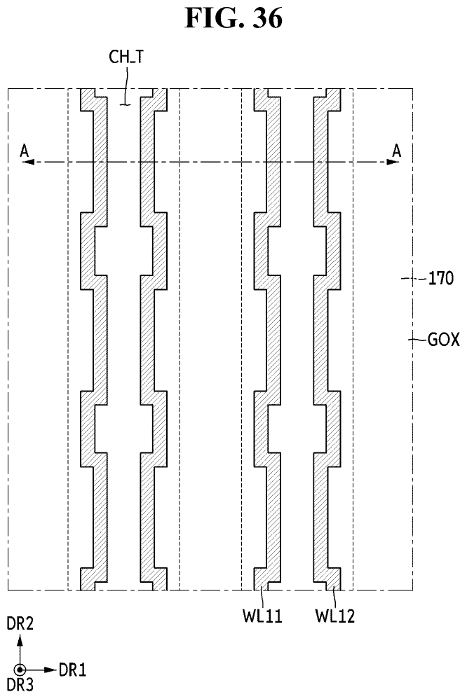

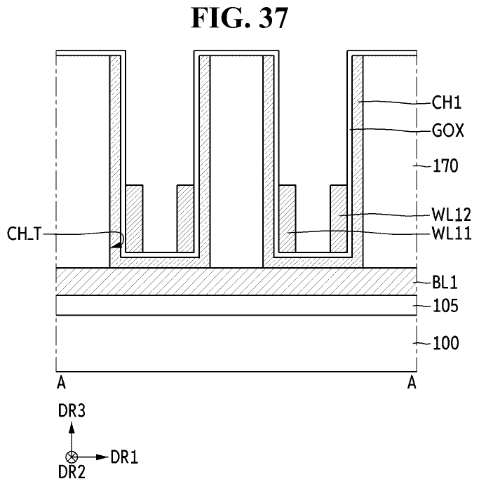

Referring to FIGS. 36 and 37, the first word lines WL11 and WL12 may be formed on the first gate insulating pattern GOX.

More specifically, a first word line film may be formed on the first gate insulating pattern GOX. The first word line film may be anisotropically etched to remove a part of the first word line film. Thus, the first word lines WL11 and WL12 may be formed along the side wall of the first channel trench CH_T.

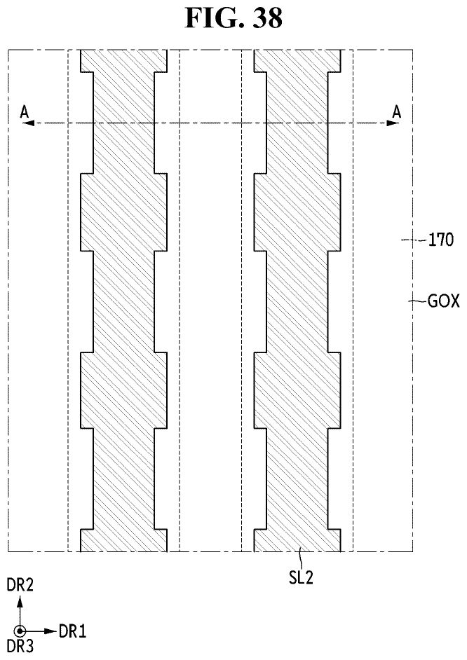

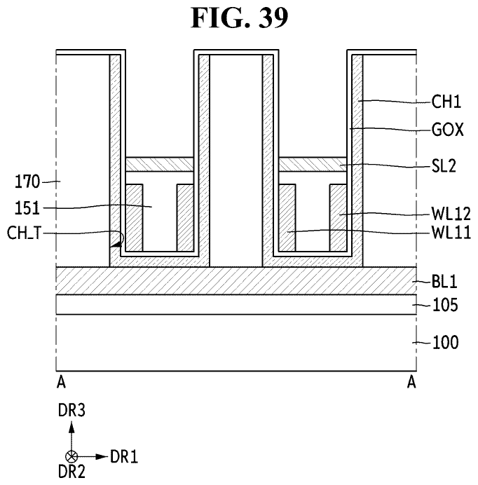

Referring to FIGS. 38 and 39, the first separation insulating pattern 151 may be formed on the first word lines WL11 and WL12.

The first separation insulating pattern 151 may fill a part of the first channel trench CH_T.

Next, a second shielding conductive pattern SL2 may be formed on the first separation insulating pattern 151. The second shielding conductive pattern SL2 may be formed inside the first channel trench CH_T.

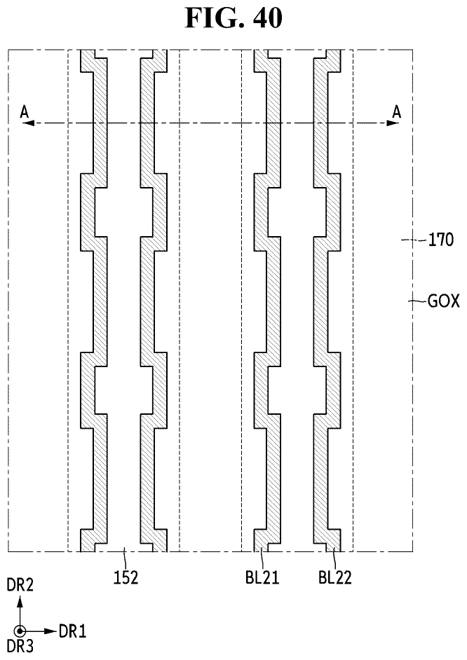

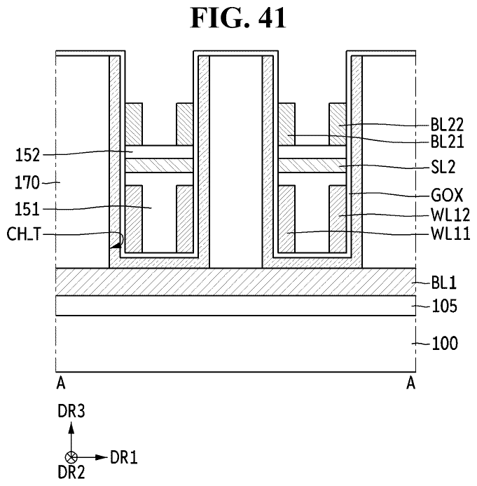

Referring to FIGS. 40 and 41, the second separation insulating pattern 152 may be formed on the second shielding conductive pattern SL2.

Next, the second bit lines BL21 and BL22 may be formed on the second separation insulating pattern 152. More specifically, a bit line film may be formed on the second separation insulating pattern 152. The bit line film may be anisotropically etched to remove a part of the bit line film. Accordingly, the second bit lines BL21 and BL22 may be formed along the side walls of the first channel trench CH_T.

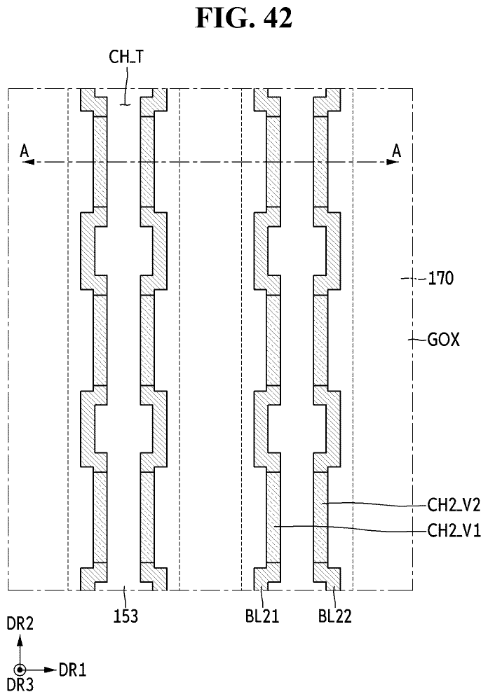

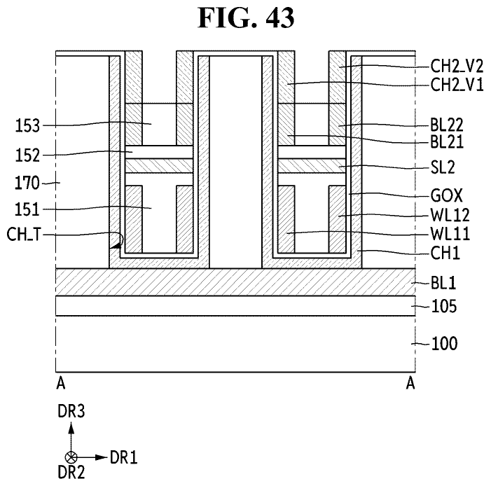

Referring to FIGS. 42 and 43, the third separation insulating pattern 153 may be formed on the second separation insulating pattern 152.

The third separation insulating pattern 153 may be formed between the second bit lines BL21 and BL22 adjacent to each other in the first direction DR1. The third separation insulating pattern 153 does not cover or does not overlap the upper surfaces of the second bit lines BL21 and BL22.

Next, the vertical portions CH2_V1 and CH2_V2 of the second channel pattern may be formed on the second bit lines BL21 and BL22.

More specifically, the first pre-channel film may be formed on the second bit lines BL21 and BL22 and the third separation insulating pattern 153. The first pre-channel film may be formed along a part of the side wall of the first channel trench CH_T and the upper surface of the first protruding insulating pattern 170. The first pre-channel film may then be patterned to form a first pre-channel pattern, like the pre-channel pattern CH1_P. From the viewpoint of a plan view, the first pre-channel pattern may have a line pattern shape extending in the first direction DR1. The first pre-channel pattern may be anisotropically etched to remove the first pre-channel pattern on the upper surface of the third separation insulating pattern 153 and the upper surface of the first protruding insulating pattern 170. As a result, the vertical portions CH2_V1 and CH2_V2 of the second channel pattern spaced apart from each other in the first direction DR1 may be formed inside the first channel trench CH_T.

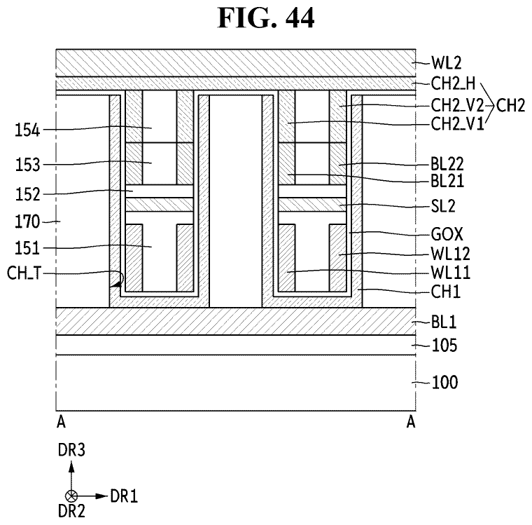

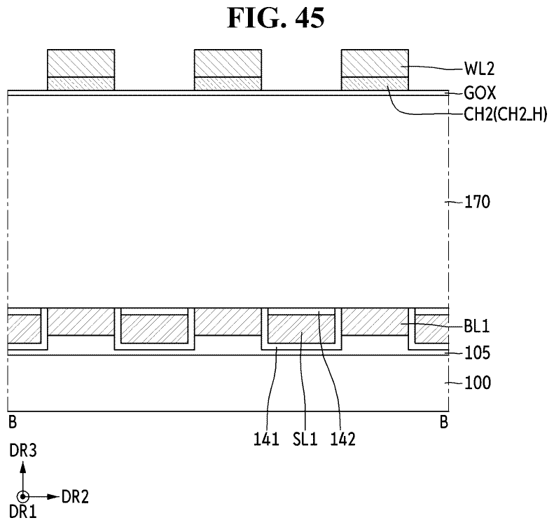

Referring to FIGS. 44 and 45, a fourth separation insulating pattern 154 may be formed on the third separation insulating pattern 153.

The fourth separation insulating pattern 154 may be formed between the vertical portions CH2_V1 and CH2_V2 of the second channel pattern adjacent to each other in the first direction DR1. The fourth separation insulating pattern 154 does not cover or does not overlap the upper surfaces of the vertical portions CH2_V1 and CH2_V2 of the second channel pattern.

Next, the horizontal portion CH2_H of the second channel pattern may be formed on the fourth separation insulating pattern 154 and the vertical portions CH2_V1 and CH2_V2 of the second channel pattern. The second word line WL2 may be formed on the horizontal portion CH2_H of the second channel pattern.

Next, referring to FIGS. 4 to 6, the second shielding conductive pattern SL3 may be formed on the second word line WL2.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. A semiconductor device comprising:
a first bit line which extends in a first direction, wherein a first surface and a second surface of the first bit line are opposite to each other in a second direction perpendicular to the first direction, and a side wall of the first bit line extends from the first surface of the first bit line to the second surface of the first bit line;
a first channel pattern on the first surface of the first bit line, and is in contact with the first bit line;
a first word line which extends in a third direction perpendicular to the first direction and the second direction, and is on the first channel pattern;
a second bit line which extends in the third direction, and overlaps the first word line in the second direction;
a first shielding conductive pattern between the first word line and the second bit line, and extends in the third direction;
a second channel pattern on the second bit line, and is in contact with the second bit line;
a gate insulating pattern between the first channel pattern and the first word line, and between the first channel pattern and the second channel pattern; and
a second word line which extends in the first direction and is on the second channel pattern.

2. The semiconductor device of claim 1, further comprising:
a second shielding conductive pattern on the side wall of the first bit line and extends in the first direction.

3. The semiconductor device of claim 1, further comprising:
a second shielding conductive pattern on the second channel pattern and on a side wall of the second word line,
wherein a first surface of the second word line faces the second channel pattern, and
wherein the side wall of the second word line extends from the first surface of the second word line to a second surface of the second word line.

4. The semiconductor device of claim 3,
wherein the second shielding conductive pattern is on the second surface of the second word line.

5. The semiconductor device of claim 1,
wherein the second channel pattern comprises a horizontal portion extending in the first direction, and a vertical portion extending in the second direction,
wherein the vertical portion of the second channel pattern overlaps the first channel pattern in the first direction, and
wherein the horizontal portion of the second channel pattern is spaced apart from the first channel pattern in the second direction, and is in contact with the second word line.

6. The semiconductor device of claim 1,
wherein the first channel pattern comprises a horizontal portion extending in the first direction, and a vertical portion extending in the second direction, and
wherein the first surface of the first bit line is in contact with the horizontal portion of the first channel pattern.

7. The semiconductor device of claim 6,
wherein the vertical portion of the first channel pattern includes a first side wall and a second side wall opposite each other in the first direction, and
wherein the first word line, the first shielding conductive pattern, the second bit line, and the second channel pattern are on the first side wall of the vertical portion of the first channel pattern.

8. The semiconductor device of claim 1,
wherein the gate insulating pattern is between the first shielding conductive pattern and the first channel pattern, and between the second bit line and the first channel pattern.

9. The semiconductor device of claim 1,
wherein the first channel pattern and the second channel pattern each comprise a metal oxide semiconductor.

10. The semiconductor device of claim 1,
wherein the first channel pattern comprises a metal oxide semiconductor, and
wherein the second channel pattern comprises polycrystalline silicon.

11. A semiconductor device comprising:
a first bit line which extends in a first direction, wherein a first surface and a second surface of the first bit line are opposite to each other in a second direction perpendicular to the first direction, and a side wall of the first bit line extends from the first surface of the first bit line to the second surface of the first bit line;
a protruding insulating pattern on the first surface of the first bit line, and comprises a channel trench extending in a third direction perpendicular to the first direction and the second direction;
a first channel pattern which extends along a side wall and a bottom surface of the channel trench, and is in contact with the first bit line;
a first lower word line on the first channel pattern, and extends in the third direction;
a second lower word line on the first channel pattern, extends in the third direction, and is spaced apart from the first lower word line in the first direction;
a first upper bit line which extends in the third direction, and is in the channel trench;
a second upper bit line which extends in the third direction, and is spaced apart from the first upper bit line in the first direction;
a first shielding conductive pattern between the first lower word line and the first upper bit line, and between the second lower word line and the second upper bit line;
a second channel pattern on the first upper bit line and the second upper bit line, and is in contact with the first upper bit line and the second upper bit line; and
a second word line which extends in the first direction and is on an upper surface of the protruding insulating pattern.

12. The semiconductor device of claim 11,
wherein the first shielding conductive pattern extends in the third direction and is in the channel trench.

13. The semiconductor device of claim 11, further comprising:
a second shielding conductive pattern on the side wall of the first bit line and extends in the first direction.

14. The semiconductor device of claim 11, further comprising:
a second shielding conductive pattern on the second word line, and comprises a shielding conductive plate and a shielding conductive line pattern,
wherein the shielding conductive line pattern protrudes from the shielding conductive plate in the second direction.

15. The semiconductor device of claim 11,
wherein the second channel pattern includes a horizontal portion extending in the first direction, and a plurality of vertical portions extending in the second direction, and
wherein each vertical portion of the plurality of vertical portions of the second channel pattern protrude from the horizontal portion of the second channel pattern toward the first bit line.

16. The semiconductor device of claim 15,
wherein the horizontal portion of the second channel pattern is on an upper surface of the protruding insulating pattern, and
wherein the first upper bit line and the second upper bit line are each in contact with ones of the plurality of vertical portions of the second channel pattern.

17. The semiconductor device of claim 15,
wherein a first vertical portion of the plurality of vertical portions of the second channel pattern overlaps the first channel pattern in the first direction.

18. The semiconductor device of claim 11,
wherein the first upper bit line overlaps the first lower word line in the second direction, and
wherein the second upper bit line overlaps the second lower word line in the second direction.

19. A semiconductor device comprising:
a first bit line which extends in a first direction;
a lower shielding conductive pattern which extends in the first direction, and is spaced apart from the first bit line in a second direction perpendicular to the first direction;
a first channel pattern on the first bit line and the lower shielding conductive pattern, and is in contact with the first bit line;
a first word line which extends in the second direction, and is on the first channel pattern;
a second bit line which extends in the second direction, and overlaps the first word line in a third direction perpendicular to the first direction and the second direction;
an intermediate shielding conductive pattern between the first word line and the second bit line, and extends in the second direction;
a second channel pattern on the second bit line, and is in contact with the second bit line;
a second word line which extends in the first direction, and is on the second channel pattern; and
an upper shielding conductive pattern on the second word line.

20. The semiconductor device of claim 19, further comprising:
a protruding insulating pattern on the first bit line and the lower shielding conductive pattern, and includes a channel trench extending in the second direction,
wherein the first channel pattern extends along a side wall and a bottom surface of the channel trench, and
wherein the first word line, the second bit line, and the intermediate shielding conductive pattern are each in the channel trench.
